(19) United States
(12) Patent Application Publication
(10) Pub. No.: US 2026/0198073 A1
(43) Pub. Date: Jul. 9, 2026

(54) SEMICONDUCTOR DEVICE

(71) Applicant: ROHM CO., LTD., Kyoto-shi (JP)

(72) Inventor: Takui SAKAGUCHI, Kyoto-shi (JP)

(73) Assignee: ROHM CO., LTD., Kyoto-shi (JP)

(21) Appl. No.: 19/553,689

(22) Filed: Mar. 2, 2026

Related U.S. Application Data
(63) Continuation of application No. PCT/JP2024/028788, filed on Aug. 9, 2024.

(30) Foreign Application Priority Data
Sep. 11, 2023 (JP) 2023-146861

(51) Int. Cl. H10D 84/00; H10D 8/00; H10D 8/60; H10D 30/66; H10D 62/10; H10D 62/60

(52) U.S. Cl. CPC H10D 84/146; H10D 8/411; H10D 8/60; H10D 30/665; H10D 62/107; H10D 62/126; H10D 62/60; H10D 84/143

(57) ABSTRACT

A semiconductor device includes a base impurity region of a second conductivity type formed in a surface layer portion of a semiconductor region of a first conductivity type and having a band shape that is long in a first direction, a first impurity region formed in a surface layer portion of the base impurity region, a gate electrode formed in a band shape that is long in the first direction and facing a channel region of the base impurity region via a gate insulating film, a Schottky region formed by a portion of the semiconductor region and dividing the base impurity region into a plurality of unit cells in a second direction intersecting the first direction, and a principal surface electrode that is in Schottky junction with the Schottky region.

### CROSS-REFERENCE TO RELATED APPLICATIONS

The present application is a bypass continuation application of International Patent Application No. PCT/JP2024/028788, filed on Aug. 9, 2024, which corresponds to Japanese Patent Application No. 2023-146861 filed on Sep. 11, 2023 with the Japan Patent Office, and the entire disclosure of these applications are incorporated herein by reference.

### TECHNICAL FIELD

The present disclosure relates to a semiconductor device.

### BACKGROUND ART

Patent Literature 1 (Japanese Patent Application Publication No. 2022-168307) discloses a semiconductor device including: a semiconductor layer having a first principal surface; a unit cell including an n-type (first conductivity type) diode region formed in a surface layer portion of the first principal surface, a p-type (second conductivity type) well region formed around the diode region in the surface layer portion of the first principal surface, and an n-type impurity region formed in a surface layer portion of the well region; a gate electrode layer facing the well region and the impurity region with a gate insulating layer interposed therebetween; and a first principal surface electrode covering the diode region and the impurity region on the first principal surface and forming a Schottky junction with the diode region.

### BRIEF DESCRIPTION OF DRAWINGS

FIG. 1 is a plan view of a semiconductor device according to a preferred embodiment of the present disclosure.

FIG. 2 is a sectional view taken along line II-II shown in FIG. 1.

FIG. 3 is a plan view illustrating a layout example of a first principal surface.

FIG. 4 is an enlarged plan view illustrating a main portion of the first principal surface.

FIG. 5 is an enlarged plan view illustrating another main portion of the first principal surface.

FIG. 6 is a plan view illustrating a layout example of an impurity region and a gate structure on the first principal surface.

FIG. 7 is a perspective view illustrating the layout example of the impurity region and the gate structure on the first principal surface.

FIGS. 8A and 8B are enlarged perspective views illustrating portions surrounded by an alternate long and two short dashed line VIIIA and an alternate long and two short dashed line VIIIB in FIG. 6, respectively.

FIGS. 9A and 9B are sectional views taken along line IXA-IXA illustrated in FIG. 8A and line IXB-IXB illustrated in FIG. 8B, respectively.

FIGS. 10A and 10B are sectional views taken along line XA-XA illustrated in FIG. 8A and line XB-XB illustrated in FIG. 8B, respectively.

FIGS. 11A and 11B are sectional views taken along line XIA-XIA illustrated in FIG. 8A and line XIB-XIB illustrated in FIG. 8B, respectively.

FIGS. 12A and 12B are sectional views taken along line XIIA-XIIA illustrated in FIG. 8A and line XIIB-XIIB illustrated in FIG. 8B, respectively.

FIGS. 13A and 13B are sectional views taken along line XIIIA-XIIIA illustrated in FIG. 8A and line XIIIB-XIIIB illustrated in FIG. 8B, respectively.

FIG. 14 is a sectional view taken along line XIV-XIV shown in FIG. 5.

FIG. 15 is a graph showing measurement results of current-voltage characteristics showing an effect of suppressing current-induced degradation.

FIG. 16 is a plan view illustrating a layout example (Modification Example 1) of the impurity region and the gate structure on the first principal surface.

FIG. 17 is a plan view illustrating a layout example (Modification Example 2) of the impurity region and the gate structure on the first principal surface.

FIG. 18 is a plan view illustrating a layout example (Modification Example 3) of the impurity region and the gate structure on the first principal surface.

FIG. 19 is a sectional view illustrating a modification example of an element structure of the semiconductor device.

### DESCRIPTION OF EMBODIMENTS

Next, a preferred embodiment of the present disclosure shall be described in detail with reference to the attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially” is used in this description, the wording includes a numerical value (mode) equal to a numerical value (mode) of a comparison target and also includes numerical errors (mode errors) in a range of ±10% on a basis of the numerical value (mode) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “n-type” may be referred to as a “first conductivity type” and the “p-type” may be referred to as a “second conductivity type.” As a matter of course, the “p-type” may be referred to as the “first conductivity type” and the “n-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

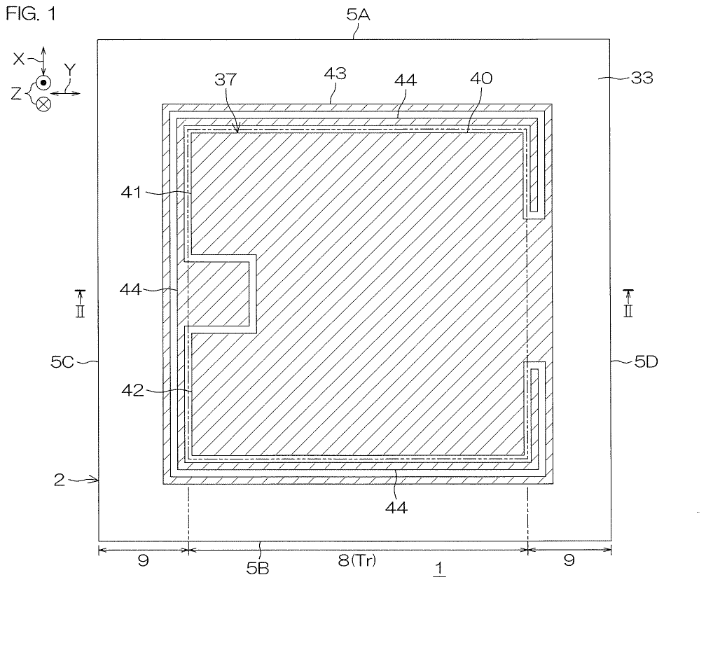

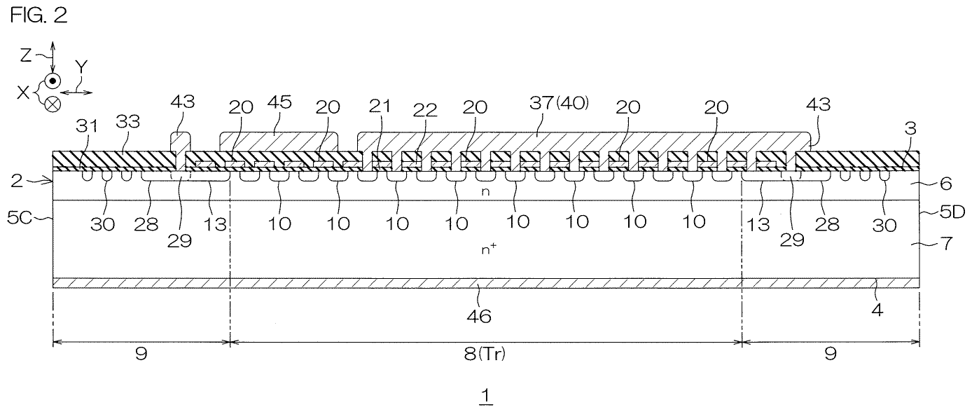

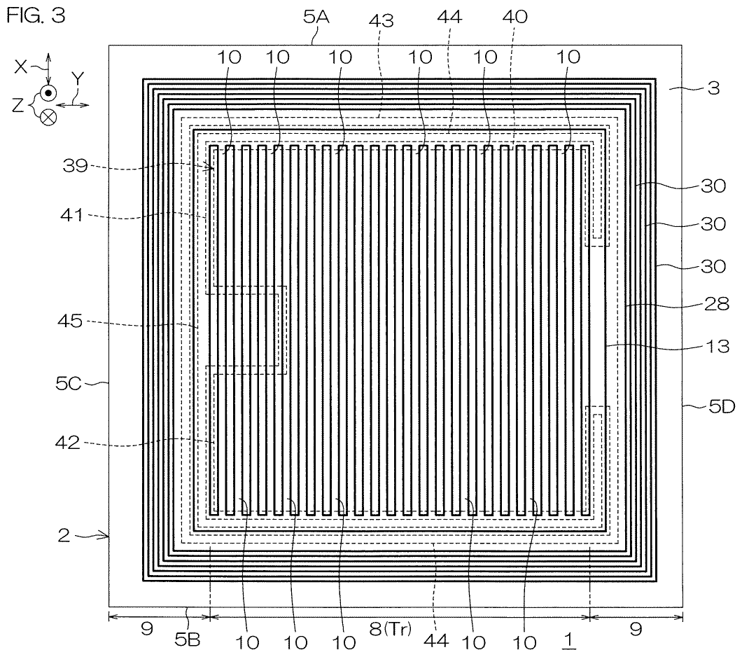

FIG. 1 is a plan view of a semiconductor device 1 according to a preferred embodiment of the present disclosure. FIG. 2 is a sectional view taken along line II-II shown in FIG. 1. FIG. 3 is a plan view illustrating a layout example of a first principal surface 3.

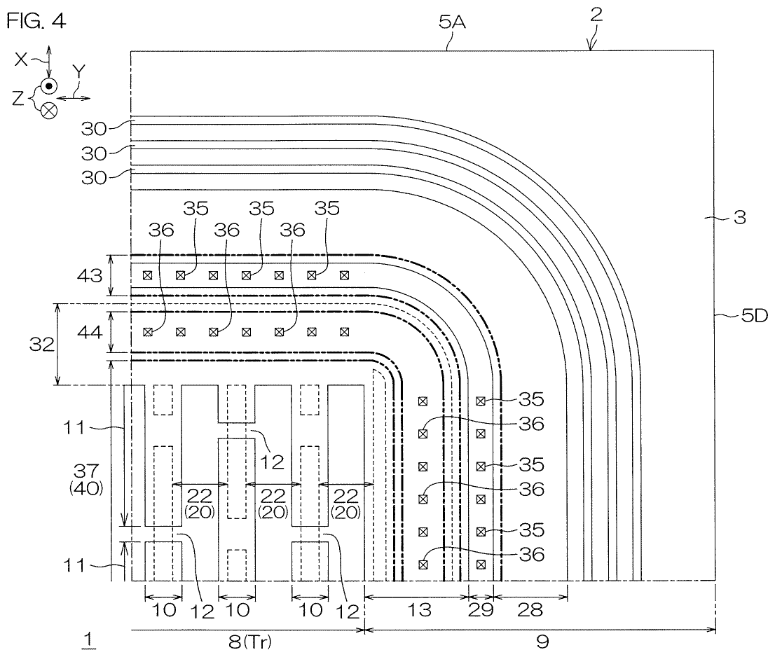

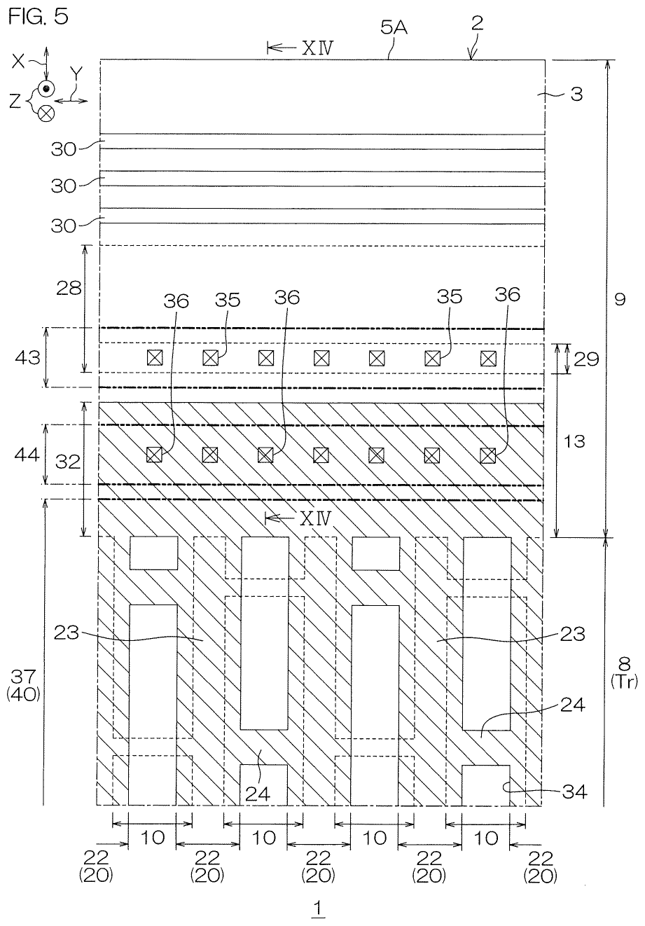

FIG. 4 is an enlarged plan view illustrating a main portion of the first principal surface 3. In FIG. 4, the outline of a gate structure 20 is indicated by a broken line. FIG. 5 is an enlarged plan view illustrating another main portion of the first principal surface 3. In FIG. 5, the gate structure 20 is indicated as a hatched region, and a plurality of body regions 10 are indicated in a broken line.

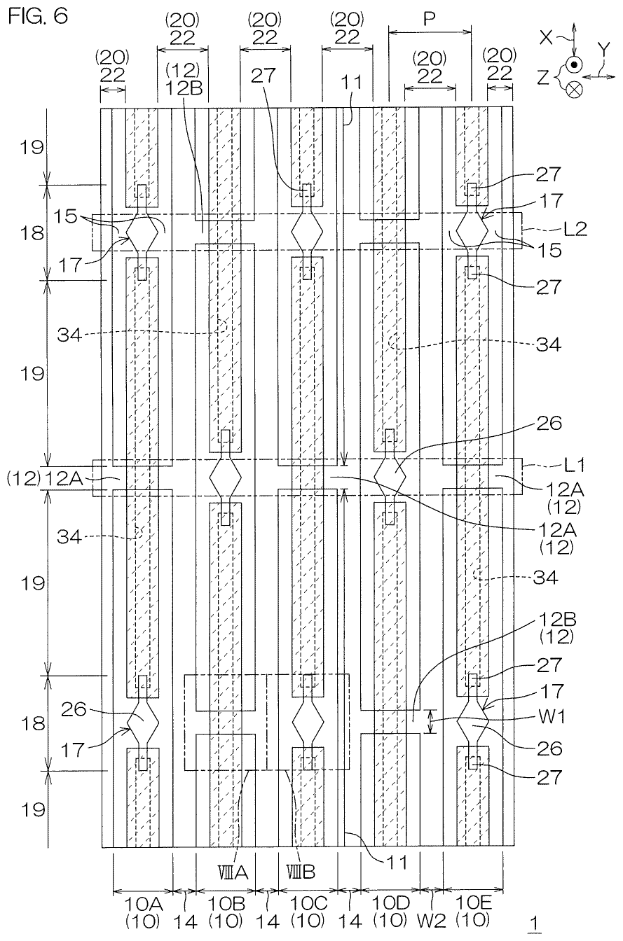

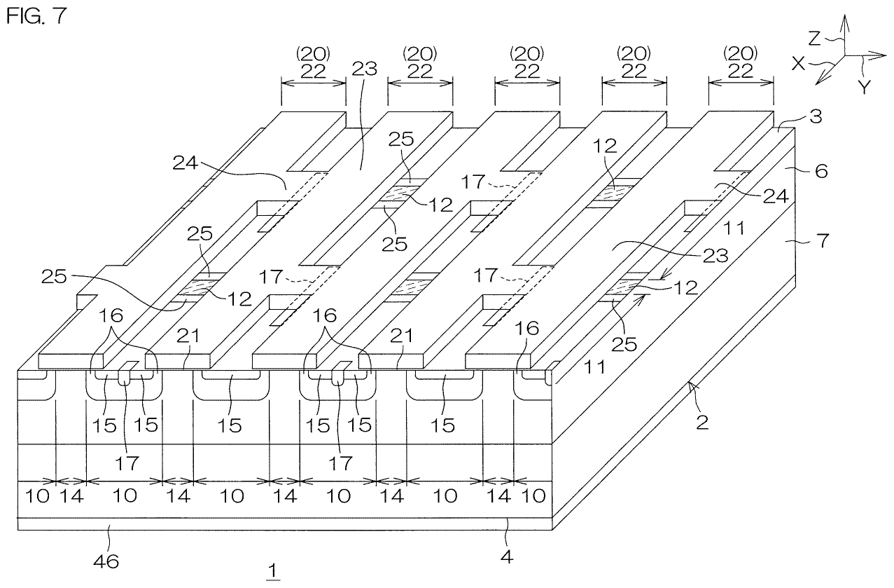

FIG. 6 is a plan view illustrating a layout example of an impurity region and the gate structure 20 on the first principal surface 3. In FIG. 6, an opening portion of a gate electrode 22 (a region from which the gate electrode 22 is removed) is indicated as a hatched region, and a contact opening 34 is indicated by a broken line. FIG. 7 is a perspective view illustrating the layout example of the impurity region and the gate structure 20 on the first principal surface 3. In FIG. 7, a Schottky region 12 is indicated as a hatched region.

Referring to FIGS. 1 to 5, the semiconductor device 1 is a semiconductor switching device having a transistor structure Tr of an insulated gate type as an example of an element structure. The transistor structure Tr has a vertical structure. The semiconductor device 1 is an SiC semiconductor device having a chip 2 containing an SiC monocrystal. The chip 2 may be referred to as an “SiC chip” or as a “semiconductor chip.”

In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has the first principal surface 3 on one side, a second principal surface 4 on another side, and first to fourth side surfaces 5A to 5D connecting the first principal surface 3 and the second principal surface 4. In plan view as viewed in a vertical direction Z (hereinafter referred to simply as a “plan view”), the first principal surface 3 and the second principal surface 4 are each formed in a quadrangular shape. The vertical direction Z is also a thickness direction of the chip 2 and a normal direction to the first principal surface 3 (second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane ((0001) plane) of the SiC monocrystal and the second principal surface 4 is formed by a carbon plane ((000-1) plane) of the SiC monocrystal.

The third side surface 5C and the fourth side surface 5D extend in a first direction X along the first principal surface 3 and face each other in a second direction Y intersecting the first direction X along the first principal surface 3. Specifically, the second direction Y is orthogonal to the first direction X. The first side surface 5A and the second side surface 5B extend in the second direction Y and face each other in the first direction X.

In the following description, one side in the first direction X means the first side surface 5A side, and the other side in the first direction X means the second side surface 5B side. One side in the second direction Y means the third side surface 5C side, and the other side in the second direction Y means the fourth side surface 5D side. Also, in this embodiment, the first direction X is an a-axis direction ([11-20] direction) of the SiC monocrystal and the second direction Y is an m-axis direction ([1-100] direction) of the SiC monocrystal. As a matter of course, the first direction X may be the m-axis direction of the SiC monocrystal and the second direction Y may be the a-axis direction of the SiC monocrystal instead.

The chip 2 (the first principal surface 3 and the second principal surface 4) has an off angle inclined at a predetermined angle in a predetermined off direction with respect to the c-plane of the SiC monocrystal. That is, a c-axis ((0001) axis) of the SiC monocrystal is inclined by just the off angle toward the off direction from the vertical axis. Also, the c-plane of the SiC monocrystal is inclined by just the off angle with respect to the horizontal plane.

The off direction is preferably the a-axis direction (that is, the first direction X) of the SiC monocrystal. The off angle may exceed 0° and be 100 or less. The off angle may have a value belonging to at least one range among exceeding 0° and being 10 or less, being 10 or more and 2.5° or less, being 2.5° or more and 5° or less, being 5° or more and 7.5° or less, and being 7.5° or more and 100 or less.

The off angle is preferably 5° or less. The off angle is particularly preferably 2° or more and 4.5° or less. The off angle is typically set in a range of 4°+0.1°. This description does not exclude an embodiment in which the off angle is 0° (that is, an embodiment in which the first principal surface 3 is a just surface with respect to the c-plane).

The semiconductor device 1 includes a first semiconductor region 6 of the n-type that is formed in a region (surface layer portion) inside the chip 2 at the first principal surface 3 side. The first semiconductor region 6 may be referred to as a “drift region,” a “drain drift region,” a “drain region,” etc. A drain potential as a high potential (first potential) is applied to the first semiconductor region 6. The first semiconductor region 6 is formed in a layer shape extending along the first principal surface 3 and is exposed from the first principal surface 3 and the first to fourth side surfaces 5A to 5D. In this embodiment, the first semiconductor region 6 consists of an epitaxial layer (specifically, an SiC epitaxial layer).

The semiconductor device 1 includes a second semiconductor region 7 of the n-type that is formed in a region (surface layer portion) inside the chip 2 at the second principal surface 4 side. A drain potential is applied to the second semiconductor region 7. The second semiconductor region 7 may be referred to as a “drain region,” etc. The second semiconductor region 7 has an n-type impurity concentration higher than that of the first semiconductor region 6 and is electrically connected to the first semiconductor region 6 inside the chip 2.

The second semiconductor region 7 is formed in a layer shape extending along the second principal surface 4 and is exposed from the second principal surface 4 and the first to fourth side surfaces 5A to 5D. In this embodiment, the second semiconductor region 7 consists of a semiconductor substrate (specifically, an SiC substrate). That is, the chip 2 has a laminated structure including the semiconductor substrate and the epitaxial layer. The second semiconductor region 7 has a thickness larger than the thickness of the first semiconductor region 6.

The semiconductor device 1 includes an active region 8 that is set in the chip 2. The active region 8 is a region that includes a device structure (transistor structure Tr) and in which an output current (drain current) is generated. The active region 8 is set in an inner portion of the chip 2 at intervals from peripheral edges (the first to fourth side surfaces 5A to 5D) of the chip 2 in plan view. The active region 8 is set in a polygonal shape (in this embodiment, a quadrangular shape) having four sides parallel to the peripheral edges of the chip 2 in plan view. A plane area of the active region 8 is preferably 50% or more and 90% or less of the plane area of the first principal surface 3.

The semiconductor device 1 includes an outer peripheral region 9 that, in the chip 2, is set outside the active region 8. The outer peripheral region 9 is provided in a region between the peripheral edges of the chip 2 and the active region 8 in plan view. The outer peripheral region 9 extends in a band shape along the active region 8 and is set to a polygonal annular shape (in this embodiment, a quadrangular annular shape) that surrounds the active region 8 in plan view.

The semiconductor device 1 includes a plurality of body regions 10 of the p-type as an example of a base impurity region formed in a surface layer portion of the first principal surface 3 in the active region 8. A source potential as a low potential (second potential) different from a high potential (first potential) is applied to the plurality of body regions 10. The plurality of body regions 10 are arrayed at intervals in the second direction Y, and are each formed in a band shape extending in the first direction X. That is, the plurality of body regions 10 are arrayed in a stripe shape extending in the first direction X.

Referring to FIG. 6, a pitch P (for example, a distance between the centers of the body regions 10 adjacent to each other in the second direction Y) of the plurality of body regions 10 is, for example, 2.5 μm or more and 5 μm or less, and preferably 3.0 μm or more and 3.6 μm or less. Also, a width W2 (second width) between the plurality of body regions 10 adjacent in the second direction Y is, for example, 0.5 μm or more and 4 μm or less, and preferably 0.6 μm or more and 1.0 μm or less.

Referring to FIG. 2, the plurality of body regions 10 are formed at intervals from a bottom portion of the first semiconductor region 6 toward the first principal surface 3, and face the second semiconductor region 7 with a portion of the first semiconductor region 6 interposed therebetween. The plurality of body regions 10 are preferably formed at intervals from an intermediate portion of the first semiconductor region 6 toward the first principal surface 3. The plurality of body regions 10 are exposed from the first principal surface 3.

With reference to FIGS. 4 to 7, the semiconductor device 1 includes the Schottky region 12 of the n-type that is formed in a surface layer portion of the first principal surface 3 in the active region 8. The Schottky region 12 is formed by a portion of the first semiconductor region 6. The Schottky region 12 is a portion of the first semiconductor region 6 exposed from the first principal surface 3.

The Schottky region 12 divides each body region 10 into a plurality of unit cells 11 in the second direction Y. The Schottky region 12 divides each body region 10 by crossing each band-shaped body region 10 in the width direction. The Schottky region 12 is sandwiched between the plurality of body regions 10 (the unit cells 11) adjacent to each other in the first direction X.

In this embodiment, a plurality of Schottky regions 12 dividing each of the plurality of body regions 10 adjacent to each other in the second direction Y are disposed at positions shifted from each other in the second direction Y. For example, the plurality of body regions 10 shown in FIG. 6 are defined as a first body region 10A, a second body region 10B, a third body region 10C, a fourth body region 10D, and a fifth body region 10E, respectively, from the left side of the sheet. The first to fifth body regions 10A to 10E are denoted by different terms for convenience of structure description of the semiconductor device 1, but functions as transistors are the same.

For example, the Schottky region 12 dividing one body region 10 (for example, the first body region 10A) does not face the Schottky region 12 dividing the second body region 10B adjacent to the right side of the first body region 10A in the second direction Y, and is disposed at a position away therefrom in the first direction X. Similarly, the Schottky region 12 dividing the third body region 10C does not face the Schottky region 12 dividing the fourth body region 10D adjacent to the right side of the third body region 10C in the second direction Y, and is disposed at a position away therefrom in the first direction X. Also, the Schottky region 12 dividing the first body region 10A faces the Schottky region 12 dividing the third body region 10C with the second body region 10B interposed therebetween in the second direction Y.

More specifically, the plurality of Schottky regions 12 can be divided into two regions of a first Schottky region 12A and a second Schottky region 12B based on an array pattern. In FIG. 6, the first Schottky region 12A is a Schottky region 12 that divides the first body region 10A, the third body region 10C, and the fifth body region 10E, and forms a first array line L1 in the second direction Y. On the other hand, the second Schottky region 12B is a Schottky region 12 that divides the second body region 10B and the fourth body region 10D at a position shifted from the first array line L1 in the first direction X, and forms a second array line L2 in the second direction Y. As a result, the plurality of first Schottky regions 12A and the plurality of second Schottky regions 12B are formed in every other of the plurality of body regions 10 arrayed in the second direction Y.

Referring to FIG. 6, a width W1 (first width) of the Schottky region 12 in the first direction X is equal to or less than the width W2 between the plurality of adjacent body regions 10. For example, the width W1 is 0.5 μm or more and 2 μm or less, and preferably 0.6 μm or more and 1.0 μm or less. When the width W1 is equal to or less than the width W2 (W1≤W2), the plurality of body regions 10 (the unit cells 11) between which the Schottky region 12 sandwiched can be brought relatively close to each other, such that the electric field in the first semiconductor region 6 can be dispersed in the body region 10. Thus, electric field concentration in the Schottky region 12 can be suppressed.

Referring to FIGS. 2 to 5, the semiconductor device 1 includes an outer body region 13 of the p-type formed in the surface layer portion of the first principal surface 3 in the outer peripheral region 9. The outer body region 13 preferably has a p-type impurity concentration substantially equal to a p-type impurity concentration of the body region 10. As a matter of course, the p-type impurity concentration of the outer body region 13 may be less than the p-type impurity concentration of the body region 10, or may be higher than the p-type impurity concentration of the body region 10.

The outer body region 13 is formed at intervals from the peripheral edges (the first to fourth side surfaces 5A to 5D) of the first principal surface 3 toward the active region 8, and extends in a band shape along the active region 8. The outer body region 13 has a portion extending in a band shape in the first direction X and a portion extending in a band shape in the second direction Y in plan view, and demarcates the active region 8 in a plurality of directions.

In this embodiment, the outer body region 13 surrounds the active region 8 in plan view and is demarcated in a polygonal annular shape (in this embodiment, a quadrangular annular shape) having four sides parallel to the peripheral edges of the first principal surface 3. That is, the outer body region 13 forms a boundary portion between the active region 8 and the outer peripheral region 9. The outer body region 13 may have an edge portion connecting the portion extending in the first direction X and the portion extending in the second direction Y in plan view in an arcuate shape (preferably a quadrant arcuate shape) (see FIG. 4).

The outer body region 13 has an inner edge portion on the active region 8 side and an outer edge portion on the peripheral edge side of the first principal surface 3. The inner edge portion of the outer body region 13 is connected to the plurality of body regions 10 in the portion extending in the second direction Y. Thus, the outer body region 13 is fixed at the same potential as the plurality of body regions 10.

The outer body region 13 preferably has a width larger than a width of the body region 10. The width of the body region 10 is a width in a direction orthogonal to an extension direction (that is, the second direction Y). The width of the outer body region 13 is a width in a direction orthogonal to the extension direction. As a matter of course, the width of the outer body region 13 may be substantially equal to the width of the body region 10, or may be less than a thickness of the body region 10.

The ratio of the width of the outer body region 13 to the width of the body region 10 may be 10 or more and 50 or less. The width ratio is preferably 20 or more and 40 or less.

Referring to FIG. 2, the outer body regions 13 are formed at intervals from a bottom portion of the first semiconductor region 6 toward the first principal surface 3, and face the second semiconductor region 7 with a portion of the first semiconductor region 6 interposed therebetween. The outer body region 13 is preferably formed at an interval from the intermediate portion of the first semiconductor region 6 toward the first principal surface 3. The outer body region 13 is exposed from the first principal surface 3.

The outer body region 13 preferably has a thickness (depth) substantially equal to the thickness (depth) of the body region 10. As a matter of course, the thickness of the outer body region 13 may be less than the thickness of the body region 10, or may be larger than the thickness of the body region 10.

Referring to FIGS. 6 and 7, the semiconductor device 1 includes a plurality of surface layer drift regions 14 of the n-type formed in the surface layer portion of the first principal surface 3. In this embodiment, each of the plurality of surface layer drift regions 14 is constituted of a portion of the first semiconductor region 6. As a matter of course, the plurality of surface layer drift regions 14 may have an n-type impurity concentration higher than the n-type impurity concentration of the first semiconductor region 6, or may have an n-type impurity concentration lower than the n-type impurity concentration of the first semiconductor region 6.

The plurality of surface layer drift regions 14 are each demarcated in a region between the plurality of body regions 10 adjacent to each other in the second direction Y. Specifically, the plurality of surface layer drift regions 14 are each demarcated by the plurality of body regions 10 and the outer body region 13 in the surface layer portion of the first principal surface 3. The plurality of surface layer drift regions 14 are arrayed at intervals in the first direction X, and are each formed in a band shape extending in the first direction X. That is, the plurality of surface layer drift regions 14 are formed in a stripe shape extending in the first direction X.

The plurality of adjacent surface layer drift regions 14 are integrally connected by the Schottky region 12. Therefore, on the first principal surface 3, the plurality of stripe-shaped surface layer drift regions 14 are alternately connected to the plurality of Schottky regions 12, such that impurity regions of the first conductivity type (in this embodiment, n-type impurity regions) defining a brick pattern in plan view are exposed. As a result, the plurality of band-shaped body regions 10 (the unit cells 11) are arrayed in the brick pattern in plan view.

Referring to FIG. 7, the semiconductor device 1 includes a source region 15 of the n-type as an example of a first impurity region formed in each of the surface layer portions of the plurality of body regions 10. The source region 15 has an n-type impurity concentration higher than the n-type impurity concentration of the first semiconductor region 6. A source potential is applied to the source region 15. In FIGS. 4 and 5, illustration of the source region 15 is omitted for clarity.

Referring to FIG. 7, the semiconductor device 1 includes a plurality of channel regions 16 of the p-type formed in the surface layer portion of the first principal surface 3. The plurality of channel regions 16 are demarcated in regions between end portions of the plurality of body regions 10 (the plurality of surface layer drift regions 14) and peripheral edges of the source region 15, respectively, in the surface layer portions of the plurality of body regions 10. In this embodiment, the plurality of channel regions 16 are arrayed at intervals in the second direction Y and are each formed in a band shape extending in the first direction X. That is, the plurality of channel regions 16 are arrayed in a stripe shape extending in the first direction X.

Referring to FIGS. 6 and 7, the semiconductor device 1 includes a plurality of contact regions 17 of the p-type each formed in the surface layer portion of the plurality of body regions 10 in the active region 8. The contact region 17 may be referred to as a “back gate region.” A source potential is applied to the plurality of contact regions 17. The contact region 17 has a p-type impurity concentration higher than the p-type impurity concentration of the body region 10. In FIGS. 4 and 5, illustration of the contact region 17 is omitted for clarity.

Referring to FIG. 6, each unit cell 11 has a first section 18 and a second section 19 in the first direction X. A clear boundary does not have to be formed between the first section 18 and the second section 19. For example, in the first direction X, the first section 18 may be longer than the second section 19, or the first section 18 may be shorter than the second section 19.

The contact region 17 is selectively formed in the first section 18 such as to skip each second section 19 in the first direction X. In the body region 10, the contact region 17 and regions on both sides of the contact region 17 in the second direction Y may be the first section 18. The second section 19 may be a region from the contact region 17 to end portions on both sides of the unit cell 11 in the first direction X.

Each contact region 17 extends in a band shape in the extension direction of the unit cell 11 (the first direction X). Each contact region 17 is formed at an interval from a bottom portion of the body region 10 toward the first principal surface 3, and faces the first semiconductor region 6 with a portion of the body region 10 interposed therebetween. Each contact region 17 is formed at an interval from both peripheral edges on one side and the other side of the body region 10 in the second direction Y. In this embodiment, the contact region 17 is formed in a central portion of the body region 10 in the second direction Y. By forming the contact region 17, the source region 15 is separated into a plurality of source regions 15 in the first section 18.

From another aspect, each of the plurality of contact regions 17 is selectively formed inside the source region 15. More specifically, the plurality of contact regions 17 are disposed at positions such as to form a pattern in which the plurality of Schottky regions 12 and the plurality of contact regions 17 are alternately arrayed in the second direction Y. In this embodiment, the plurality of Schottky regions 12 and the plurality of contact regions 17 are alternately arrayed in a staggered manner in the first direction X and the second direction Y.

Therefore, in each of the first array line L1 and the second array line L2 in FIG. 6, the plurality of Schottky regions 12 and the plurality of contact regions 17 are alternately arrayed. Further, it is arranged such that the plurality of Schottky regions 12 and the plurality of contact regions 17 of the first array line L1 do not adjacent to the plurality of Schottky regions 12 and the plurality of contact regions 17 of the second array line L2 in the first direction X, respectively.

The semiconductor device 1 includes a plurality of gate structures 20 of a planar electrode type disposed on the first principal surface 3 in the active region 8. The gate structure 20 is disposed on at least one channel region 16. In this embodiment, each gate structure 20 is disposed such as to span across the two body regions 10 adjacent to each other crossing one surface layer drift region 14, and covers the plurality of channel regions 16. Specifically, each gate structure 20 is disposed such as to span across the source region 15 on one body region 10 side and the source region 15 on the other body region 10 side, and covers the surface layer drift region 14, the source region 15, and the channel region 16.

The gate structure 20 has a laminated structure including an insulating film 21 and a gate electrode 22. The insulating film 21 may include at least one among a silicon oxide film, a silicon nitride film, and a silicon oxynitride film. In this embodiment, the insulating film 21 has a single layer structure constituted of the silicon oxide film. The insulating film 21 particularly preferably includes a silicon oxide film constituted of an oxide of the chip 2.

Referring to FIG. 7, the insulating film 21 covers the first principal surface 3 in a film shape and is disposed on at least one channel region 16. In this embodiment, the insulating film 21 is disposed such as to span across the two body regions 10 adjacent to each other crossing one surface layer drift region 14, and covers the plurality of channel regions 16.

Specifically, the insulating film 21 is disposed such as to span across the source region 15 on one body region 10 side and the source region 15 on the other body region 10 side, and covers the surface layer drift region 14, the source region 15, and the channel region 16.

A thickness of the insulating film 21 may be 10 nm or more and 150 nm or less. The thickness of the insulating film 21 may have a value belonging to at least one range among 10 nm or more and 25 nm or less, 25 nm or more and 50 nm or less, 50 nm or more and 75 nm or less, 75 nm or more and 100 nm or less, 100 nm or more and 125 nm or less, and 125 nm or more and 150 nm or less. The thickness of the insulating film 21 is preferably 25 nm or more and 75 nm or less.

The gate electrode 22 is disposed on the insulating film 21 and faces at least one channel region 16 with the insulating film 21 interposed therebetween. A gate potential as a control potential is applied to the gate electrode 22. The gate electrode 22 controls inversion and non-inversion of at least one channel region 16 in response to the gate potential.

The gate electrode 22 contains a semiconductor polycrystal having conductivity. The gate electrode 22 may contain either or both of a conductive polysilicon of the p-type and a conductive polysilicon of the n-type. The conductivity type of the gate electrode 22 is adjusted according to the gate threshold voltage to be achieved. The gate electrode 22 may be referred to as a “polysilicon gate,” a “poly gate,” etc.

The gate electrode 22 includes a main body portion 23 and a bridging portion 24. In this embodiment, the main body portion 23 and the bridging portion 24 are integrally formed.

The main body portion 23 is formed in a band shape extending in the first direction X. That is, the extension direction of the main body portion 23 coincides with the off direction of the SiC monocrystal. In this embodiment, the plurality of main body portions 23 are arrayed in a stripe shape extending in the first direction X. Each main body portion 23 is disposed on the insulating film 21 such as to span across the two body regions 10 adjacent to each other crossing one surface layer drift region 14 in the second direction Y, and faces the plurality of channel regions 16 with the insulating film 21 interposed therebetween.

The bridging portion 24 crosses the body region 10 between the plurality of adjacent main body portions 23 in the second direction Y, and connects the plurality of adjacent main body portions 23. In this embodiment, the bridging portion 24 connects the plurality of adjacent main body portions 23 at a position away from the Schottky region 12 in the first direction X.

More specifically, the bridging portion 24 is selectively disposed in a region covering the contact region 17. That is, the plurality of adjacent main body portions 23 are connected by the bridging portion 24 at the position of each contact region 17, and are arranged at intervals in the second direction Y in the other portions. As a result, the plurality of Schottky regions 12 and the plurality of bridging portions 24 are alternately arrayed in a staggered manner in the first direction X and the second direction Y in plan view.

A thickness of the gate electrode 22 may be 0.1 μm or more and 2.0 μm or less. The thickness of the gate electrode 22 is preferably 0.2 μm or more and 1.0 μm or less. A width of the main body portion 23 may be, for example, 1.0 μm or more and 4.5 μm or less. The width of the main body portion 23 is a width in a direction orthogonal to an extension direction (that is, the second direction Y). A width of the bridging portion 24 may be, for example, 1.0 μm or more and 4.5 μm or less. The width of the bridging portion 24 is a width in a direction orthogonal to the extension direction (that is, the first direction X).

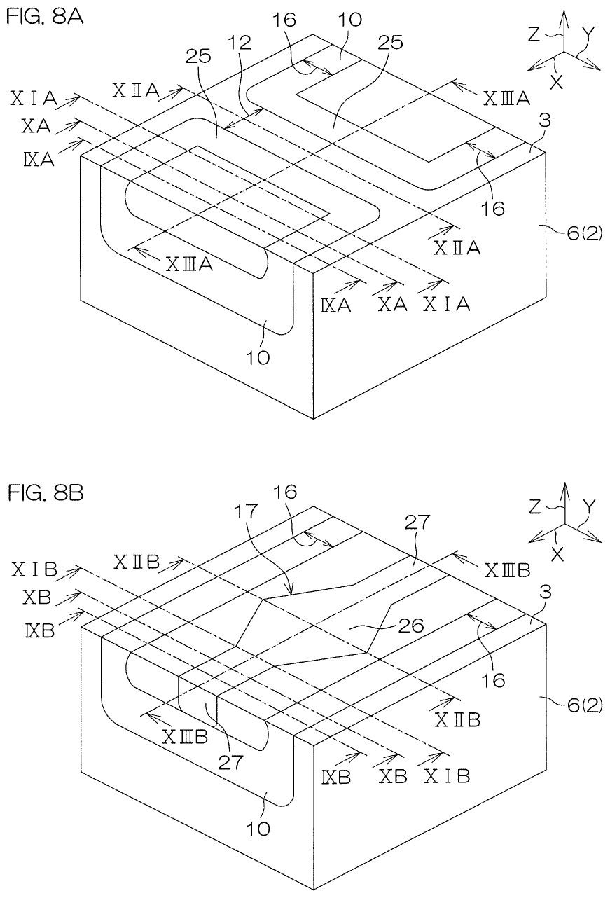

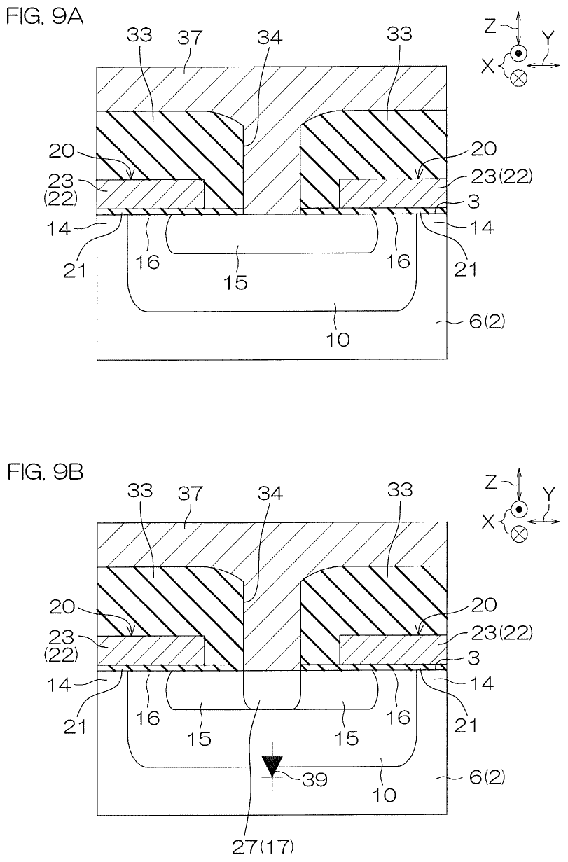

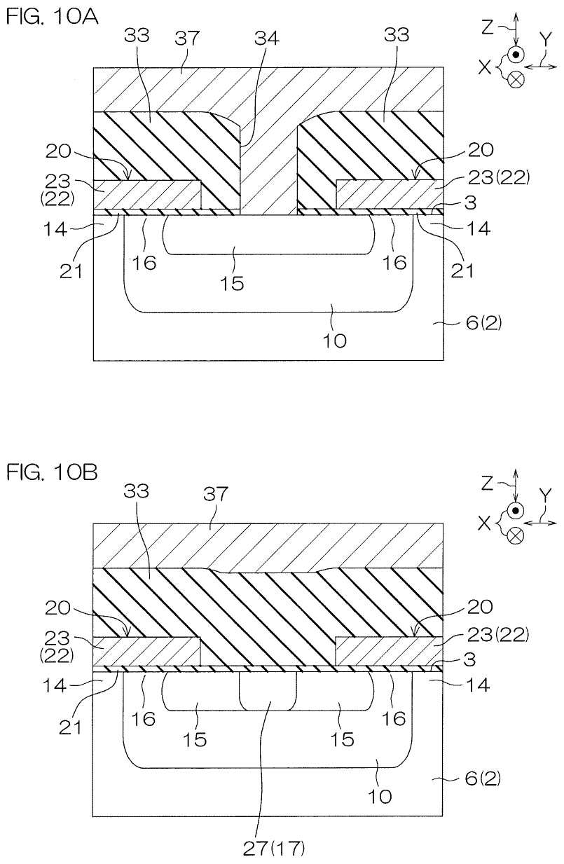

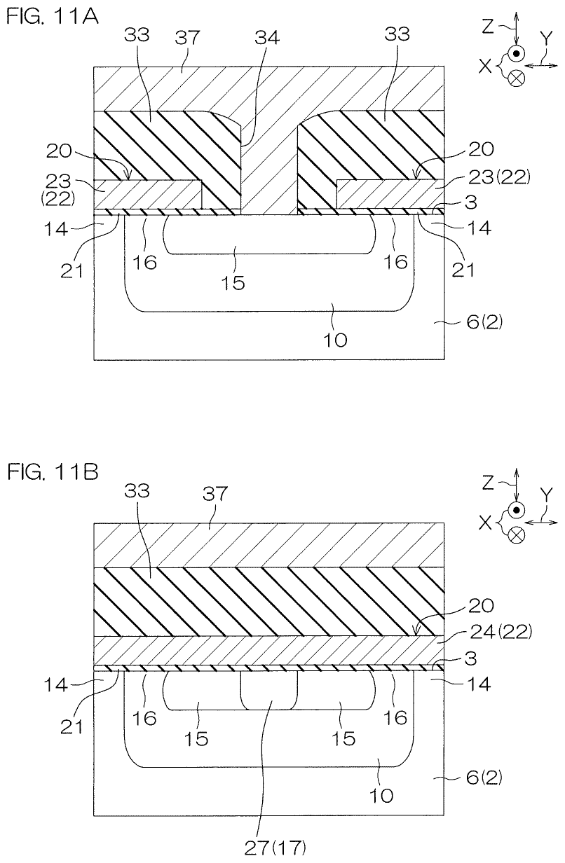

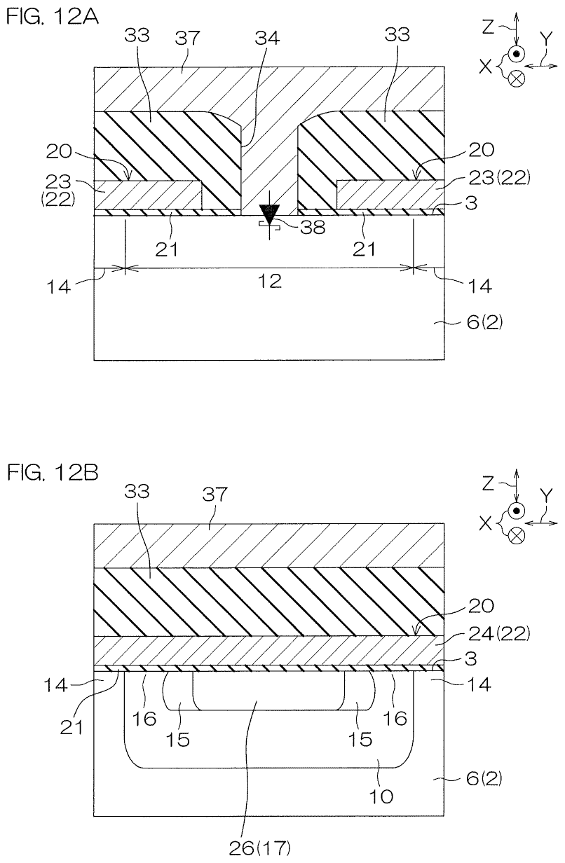

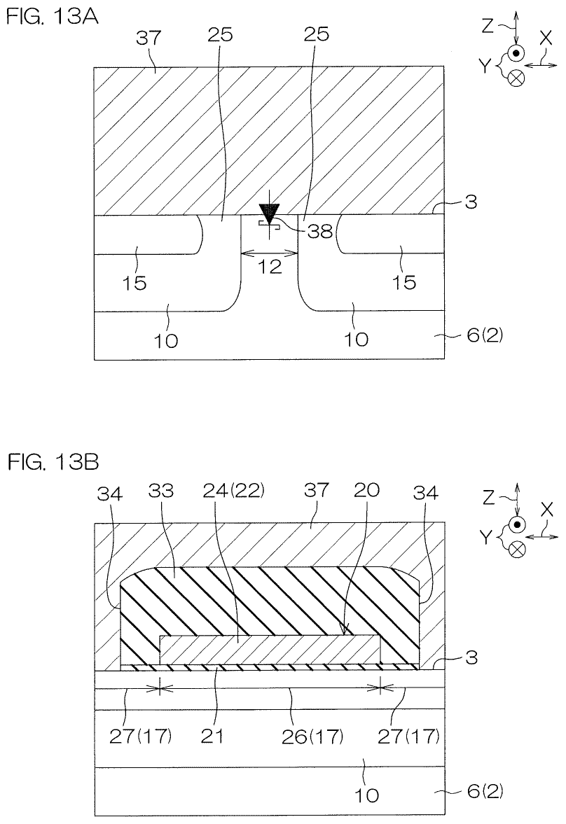

FIGS. 8A and 8B are enlarged perspective views illustrating portions surrounded by an alternate long and two short dashed line VIIIA and an alternate long and two short dashed line VIIIB in FIG. 6, respectively. FIGS. 9A and 9B are sectional views taken along line IXA-IXA illustrated in FIG. 8A and line IXB-IXB illustrated in FIG. 8B, respectively. FIGS. 10A and 10B are sectional views taken along line XA-XA illustrated in FIG. 8A and line XB-XB illustrated in FIG. 8B, respectively. FIGS. 11A and 11B are sectional views taken along line XIA-XIA illustrated in FIG. 8A and line XIB-XIB illustrated in FIG. 8B, respectively. FIGS. 12A and 12B are sectional views taken along line XIIA-XIIA illustrated in FIG. 8A and line XIIB-XIIB illustrated in FIG. 8B, respectively. FIGS. 13A and 13B are sectional views taken along line XIIIA-XIIIA illustrated in FIG. 8A and line XIIIB-XIIIB illustrated in FIG. 8B, respectively.

Next, a structure on the first principal surface 3 and a structure of peripheral portions of the Schottky region 12 and the contact region 17 shall be described in detail with reference to FIGS. 8A, 8B to 13A, and 13B.

Referring to FIG. 8A, in the plurality of body regions 10 facing each other with the Schottky region 12 interposed therebetween, the source region 15 is formed at an interval from the Schottky region 12 in the first direction X. A portion of the body region 10 is sandwiched between the source region 15 and the Schottky region 12. As illustrated in FIG. 13A, this region is a region that does not face gate electrode 22 but is in contact with a source pad electrode 37 to be described later, and may be referred to as a second contact region 25.

The second contact region 25 is made of a portion of the body region 10, and therefore has a lower impurity concentration than the contact region 17. Therefore, the second contact region 25 has higher contact resistance to the source pad electrode 37 than the contact region 17. Even when the contact resistance is high, the contact between the source pad electrode 37 and the body region 10 can be formed in the second contact region 25, such that the overall contact resistance between the source pad electrode 37 and the body region 10 can be reduced. The impurity concentration of the second contact region 25 may be made higher than that of the body region 10 by selectively introducing the impurity at the position of the second contact region 25 with a high dose amount.

Referring to FIG. 8B, the contact region 17 includes a covered portion 26 and a contact portion 27.

The covered portion 26 is formed at the center of the contact region 17 in the first direction X. The covered portion 26 may be referred to as a central portion of the contact region 17. Referring to FIGS. 12B and 13B, the covered portion 26 is a portion covered with the gate electrode 22 (the bridging portion 24) in the contact region 17.

The contact portion 27 is a portion extending from the covered portion 26 to both sides in the first direction X, and may be referred to as an extension portion of the contact region 17. The contact portion 27 extends in a band shape having a width narrower than that of the covered portion 26. In other words, the covered portion 26 is a wide portion in the contact region 17, and may have a projection portion protruding from the band-shaped contact portion 27 extending in the first direction X to both sides in the second direction Y. Referring to FIGS. 9B, 10B, 11B, 12B, and 13B, the contact portion 27 is a portion that protrudes outward in the first direction X from the gate electrode 22 (the bridging portion 24) and is exposed.

Referring to FIGS. 4, 5, and 14, the semiconductor device 1 includes a terminal region 28 of the p-type formed on the first principal surface 3 in the outer peripheral region 9. The terminal region 28 may be referred to as a “well region,” a “terminal well region,” etc. The terminal region 28 may have a p-type impurity concentration substantially equal to the p-type impurity concentration of the outer body region 13. The p-type impurity concentration of the terminal region 28 may be higher than the p-type impurity concentration of the outer body region 13, or may be lower than the p-type impurity concentration of the outer body region 13.

The terminal region 28 is formed in a region between the peripheral edges of the first principal surface 3 and the outer body region 13 at intervals inward from the peripheral edges of the first principal surface 3. The terminal region 28 extends in a band shape along the outer body region 13 in plan view. The terminal region 28 has a portion extending in a band shape in the first direction X and a portion extending in a band shape in the second direction Y in plan view, and demarcates the active region 8 in a plurality of directions.

In this embodiment, the terminal region 28 surrounds the outer body region 13 in plan view, and is demarcated in a polygonal annular shape (a quadrangular annular shape in this embodiment) having four sides parallel to the peripheral edges of the first principal surface 3. The terminal region 28 may have an edge portion connecting the portion extending in the first direction X and the portion extending in the second direction Y in plan view in an arcuate shape (preferably a quadrant arcuate shape) (see FIG. 4).

The terminal region 28 is formed at an interval from the bottom portion of the first semiconductor region 6 toward the first principal surface 3, and faces the second semiconductor region 7 with a portion of the first semiconductor region 6 interposed therebetween. The terminal region 28 is preferably formed at an interval from the intermediate portion of the first semiconductor region 6 toward the first principal surface 3. The terminal region 28 may have a thickness (depth) substantially equal to the thickness (depth) of the outer body region 13. The thickness of the terminal region 28 may be larger than the thickness of the outer body region 13, or may be smaller than the thickness of the outer body region 13.

The terminal region 28 has an inner edge portion on the active region 8 side and an outer edge portion on the peripheral edge side of the first principal surface 3. The inner edge portion of the terminal region 28 is connected to the outer edge portion of the outer body region 13. As a result, the terminal region 28 is fixed at the same potential as the outer body region 13, and is electrically connected to the plurality of body regions 10 through the outer body region 13. In this embodiment, the inner edge portion of the terminal region 28 is connected to the outer edge portion of the outer body region 13 over an entire circumference.

The terminal region 28 (inner edge portion) has an overlap region 29 overlapping the outer edge portion of the outer body region 13. The overlap region 29 is a high concentration region including the outer edge portion of the outer body region 13 and the inner edge portion of the terminal region 28. That is, the overlap region 29 includes both the p-type impurity of the outer body region 13 and the p-type impurity of the terminal region 28, and has a p-type impurity concentration higher than both the p-type impurity concentration of the outer body region 13 and the p-type impurity concentration of the terminal region 28.

The overlap region 29 extends in a band shape along the outer body region 13 in plan view. The overlap region 29 has a portion extending in a band shape in the first direction X and a portion extending in a band shape in the second direction Y in plan view, and demarcates the active region 8 in a plurality of directions. In this embodiment, the overlap region 29 is demarcated in a polygonal annular shape (a quadrangular annular shape in this embodiment) having four sides parallel to the peripheral edges of the first principal surface 3. A width of the overlap region 29 is preferably larger than the width of the body region 10. As a matter of course, the width of the overlap region 29 may be equal to or less than the width of the body region 10.

The semiconductor device 1 includes at least one (preferably, two or more and twenty or less) field region 30 of the p-type formed in the surface layer portion of the first principal surface 3 in the outer peripheral region 9. The number of the plurality of field regions 30 is typically three or more and eight or less. In this embodiment, the semiconductor device 1 includes three field regions 30. The plurality of field regions 30 are formed in an electrically floating state, and relax an electric field in the chip 2 at a peripheral edge portion of the first principal surface 3. The number, interval, width, depth, p-type impurity concentration, etc., of the field regions 30 are arbitrary, and can take various values according to the electric field to be relaxed.

The field region 30 may have a p-type impurity concentration substantially equal to the p-type impurity concentration of the body region 10 (the terminal region 28). The p-type impurity concentration of the field region 30 may be higher than the p-type impurity concentration of the body region 10 (the terminal region 28), or may be lower than the p-type impurity concentration of the body region 10 (the terminal region 28).

The plurality of field regions 30 are formed in a region between the peripheral edges of the first principal surface 3 and the active region 8 at intervals inward from the peripheral edges of the first principal surface 3. Specifically, the plurality of field regions 30 are formed in a region between the peripheral edges of the first principal surface 3 and the outer body region 13. More specifically, in a region between the peripheral edges of the first principal surface 3 and the terminal region 28, the plurality of field regions 30 are arrayed at intervals from the terminal region 28 toward the peripheral edges of the first principal surface 3.

The plurality of field regions 30 are formed in a band shape extending along the active region 8 (the terminal region 28) in plan view. Each of the plurality of field regions 30 has a portion extending in a band shape in the first direction X and a portion extending in a band shape in the second direction Y. In this embodiment, the plurality of field regions 30 are formed in a polygonal annular shape (in this embodiment, a quadrangular annular shape) surrounding the active region 8 (the terminal region 28) in plan view. The plurality of field regions 30 may have an edge portion connecting the portion extending in the first direction X and the portion extending in the second direction Y in an arcuate shape (preferably a quadrant arcuate shape) (see FIG. 4).

The plurality of field regions 30 are formed at intervals from the bottom portion of the first semiconductor region 6 toward the first principal surface 3, and face the second semiconductor region 7 with a portion of the first semiconductor region 6 interposed therebetween. The plurality of field regions 30 are preferably formed at intervals from the intermediate portion of the first semiconductor region 6 toward the first principal surface 3.

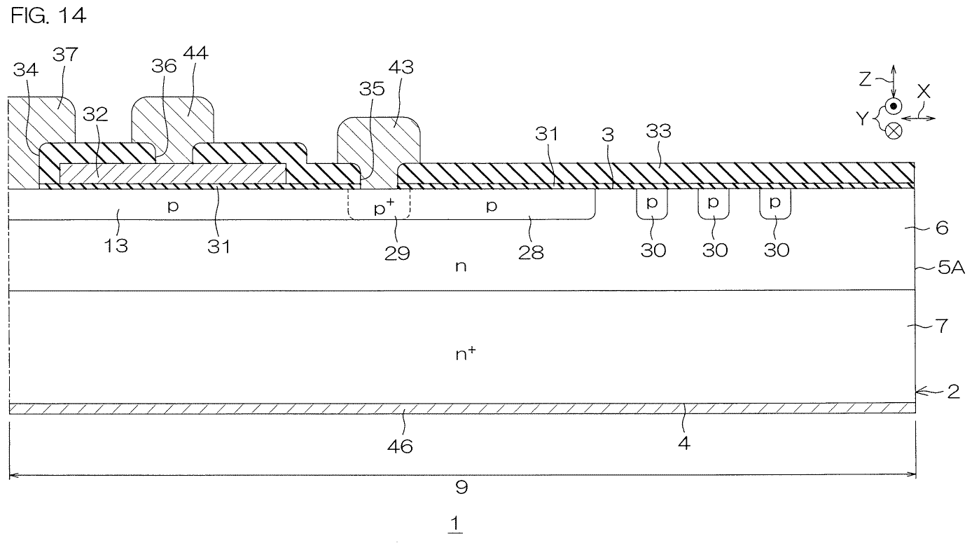

Referring to FIG. 14, the semiconductor device 1 includes an outer peripheral insulating film 31 covering the first principal surface 3 in the outer peripheral region 9. The outer peripheral insulating film 31 may include at least one among a silicon oxide film, a silicon nitride film, and a silicon oxynitride film. In this embodiment, the outer peripheral insulating film 31 has a single layer structure constituted of the silicon oxide film. The outer peripheral insulating film 31 particularly preferably includes the silicon oxide film constituted of the oxide of the chip 2. The outer peripheral insulating film 31 is preferably made of the same kind of insulating material as the insulating material of the insulating film 21. The outer peripheral insulating film 31 preferably has a thickness substantially equal to the thickness of the insulating film 21.

The outer peripheral insulating film 31 covers the first principal surface 3 in a film shape in the outer peripheral region 9. The outer peripheral insulating film 31 collectively covers the outer body region 13, the terminal region 28, and the plurality of field regions 30. The outer peripheral insulating film 31 is connected to the plurality of insulating films 21 on the active region 8 side. Specifically, the outer peripheral insulating film 31 is integrally formed with the plurality of insulating films 21, and forms one insulating film with the plurality of insulating films 21.

Referring to FIGS. 4, 5, and 14, the semiconductor device 1 includes a gate wiring 32 disposed on the first principal surface 3 in the outer peripheral region 9. The gate wiring 32 is selectively routed on the first principal surface 3 and has a portion extending in a direction different from the plurality of gate electrodes 22. The gate wiring 32 is connected to the plurality of gate electrodes 22, and applies a gate signal to the plurality of gate electrodes 22. The gate wiring 32 may be referred to as a “polysilicon gate wiring,” a “poly gate wiring,” a “second gate electrode,” etc.

The gate wiring 32 contains a semiconductor polycrystal having conductivity. The gate wiring 32 may contain either or both of a conductive polysilicon of the p-type and a conductive polysilicon of the n-type. The gate wiring 32 preferably has the same conductivity type as the conductivity type of the gate electrode 22. The conductivity type of the gate wiring 32 is adjusted according to the conductivity type of the gate electrode 22.

The gate wiring 32 is disposed on the outer peripheral insulating film 31 in the outer peripheral region 9. Specifically, the gate wiring 32 is disposed on a portion of the outer peripheral insulating film 31 covering the outer body region 13, and faces the outer body region 13 with the outer peripheral insulating film 31 interposed therebetween. The gate wiring 32 is formed at intervals from the peripheral edges of the first principal surface 3 toward the active region 8, and extends in a band shape along the active region 8. The gate wiring 32 has a portion extending in a band shape in the first direction X and a portion extending in a band shape in the second direction Y in plan view, and demarcates the active region 8 in a plurality of directions.

In this embodiment, the gate wiring 32 surrounds the active region 8 in plan view, and is demarcated in a polygonal annular shape (a quadrangular annular shape in this embodiment) having four sides parallel to the peripheral edges of the first principal surface 3. The gate wiring 32 may have a shape with ends or an endless shape. In this embodiment, the gate wiring 32 extends in a band shape (an annular shape in this embodiment) along the outer body region 13 in plan view, and faces the outer body region 13 with the outer peripheral insulating film 31 in an entire region in a lamination direction. The gate wiring 32 may have an edge portion connecting the portion extending in the first direction X and the portion extending in the second direction Y in plan view in an arcuate shape (preferably a quadrant arcuate shape) (see FIG. 4).

The gate wiring 32 is formed to be narrower than the outer body region 13 in plan view, and is disposed above the outer body region 13 at intervals from the inner edge portion and the outer edge portion of the outer body region 13. That is, in this embodiment, the plurality of gate electrodes 22 (the main body portions 23) are led out above the outer body region 13, and the gate wiring 32 is connected to the plurality of gate electrodes 22 above the outer body region 13.

A width of the gate wiring 32 is preferably larger than the width of the main body portion 23 of the gate electrode 22. The width of the gate wiring 32 is a width in a direction orthogonal to the extension direction. As a matter of course, the width of the gate wiring 32 may be equal to or less than the width of the main body portion 23 of the gate electrode 22. The width of the gate wiring 32 may be larger than the width of the outer body region 13. A thickness of the gate wiring 32 is preferably substantially equal to the thickness of the gate electrode 22.

The semiconductor device 1 includes an interlayer insulating layer 33 that covers the first principal surface 3. The interlayer insulating layer 33 may be referred to as an “interlayer insulating film,” an “intermediate insulating film,” etc. The interlayer insulating layer 33 collectively covers the active region 8 and the outer peripheral region 9 on the first principal surface 3.

Referring to FIGS. 2, 9A, 9B to 13A, and 13B, the interlayer insulating layer 33 covers the plurality of gate structures 20 in the active region 8. The interlayer insulating layer 33 directly covers both the insulating film 21 and the gate electrode 22 with respect to each gate structure 20.

Referring to FIG. 14, the interlayer insulating layer 33 collectively covers the outer body region 13, the terminal region 28, and the plurality of field regions 30 with the outer peripheral insulating film 31 in the outer peripheral region 9 interposed therebetween. The interlayer insulating layer 33 directly covers both the outer peripheral insulating film 31 and the gate wiring 32. In this embodiment, the interlayer insulating layer 33 is continuous to the first to fourth side surfaces 5A to 5D. The interlayer insulating layer 33 may be formed at intervals inward from the first to fourth side surfaces 5A to 5D and expose the peripheral edge portion (the first semiconductor region 6) of the first principal surface 3.

The interlayer insulating layer 33 may include at least one among a silicon oxide film, a silicon nitride film, and a silicon oxynitride film. In this embodiment, the interlayer insulating layer 33 may be a laminated film of a NSG film (Nondoped Silicate Glass film) and a PSG film (Phosphorus Silicon Glass film) or a BPSG film (Boron Phosphorus Silicon Glass film).

The semiconductor device 1 includes a plurality of contact openings 34 formed in the interlayer insulating layer 33 in the active region 8. The contact opening 34 may be referred to as a “source opening” or a “source contact opening.” The plurality of contact openings 34 are formed in regions at sides of the gate electrodes 22 at intervals from the gate electrodes 22, respectively, and expose the first principal surface 3 (the chip 2). Specifically, referring to FIGS. 9A, 9B to 13A, and 13B, the plurality of contact openings 34 are formed in regions between the gate electrodes 22, respectively, and pass through the insulating film 21 and the interlayer insulating layer 33.

Referring to FIG. 6, the plurality of contact openings 34 are formed to span across the plurality of unit cells 11 adjacent to each other with the Schottky region 12 interposed therebetween. Each contact opening 34 is formed in a band shape extending in the first direction X. Each band-shaped contact opening 34 crosses the Schottky region 12 between one contact region 17 and another contact region 17 from the one contact region 17 to the other contact region 17 of the plurality of unit cells 11 belonging to the same body region 10 arranged on a straight line in the first direction X.

The contact portion 27 of the contact region 17 is exposed at an end portion (in this embodiment, both end portions) of each contact opening 34. The Schottky region 12 is exposed at the central portion of each contact opening 34 in the first direction X. Also, in a large portion of each contact opening 34, the source region 15 is exposed.

Referring to FIG. 9A, etc., the contact opening 34 may have a width W3 of 0.3 μm or more and 1 μm or less. The contact opening 34 may have a depth D of 0.5 μm or more and 1 μm or less. The contact opening 34 preferably has an aspect ratio D/W3 of 0.5 or more and 2 or less. The aspect ratio D/W3 is defined by the ratio of the depth D of the contact opening 34 with respect to the width W3 of the contact opening 34. According to this configuration, the plurality of gate structures 20 are arrayed at a narrow pitch.

With reference to FIGS. 4, 5, and 14, the semiconductor device 1 includes at least one (in this embodiment, a plurality of) outer contact opening 35 that is formed in the interlayer insulating layer 33 in the outer peripheral region 9. The plurality of outer contact openings 35 are formed in a portion of the interlayer insulating layer 33 covering the terminal region 28. The plurality of outer contact openings 35 pass through the interlayer insulating layer 33 and expose the terminal region 28. In this embodiment, the plurality of outer contact openings 35 are formed in a portion of the interlayer insulating layer 33 covering the overlap region 29 of the terminal region 28 and expose the overlap region 29.

The plurality of outer contact openings 35 are formed at intervals along the terminal region 28 (the overlap region 29) (see FIGS. 4 and 5). The plurality of outer contact openings 35 may be formed in a quadrangular shape (square shape), a rectangular shape, a hexagonal shape, a circular shape, etc., in plan view. The plurality of outer contact openings 35 may be formed in a band shape extending along the terminal region 28 (the overlap region 29) in plan view. Similarly to the contact opening 34, the outer contact opening 35 may have the aspect ratio D/W3 (preferably exceeding 1).

The semiconductor device 1 may have the single outer contact opening 35. The single outer contact opening 35 may be formed in a band shape extending along the terminal region 28 (the overlap region 29). The single outer contact opening 35 may have a portion extending in a band shape in the first direction X and a portion extending in a band shape in the second direction Y in plan view.

With reference to FIGS. 4, 5, and 14, the semiconductor device 1 includes at least one (in this embodiment, a plurality of) gate contact opening 36 that is formed in the interlayer insulating layer 33 in the outer peripheral region 9. The plurality of gate contact openings 36 are formed in a portion of the interlayer insulating layer 33 covering the gate wiring 32. The plurality of gate contact openings 36 pass through the interlayer insulating layer 33 and expose the gate wiring 32.

The plurality of gate contact openings 36 are formed at intervals along the gate wiring 32 (see FIGS. 4 and 5). The plurality of gate contact openings 36 may be formed in a quadrangular shape (square shape), a rectangular shape, a hexagonal shape, a circular shape, etc., in plan view. The plurality of gate contact openings 36 may be formed in a band shape extending along the gate wiring 32 in plan view. Similarly to the contact opening 34, the gate contact opening 36 may have the aspect ratio D/W3 (preferably exceeding 1).

The semiconductor device 1 may have the single gate contact opening 36. The single gate contact opening 36 may be formed in a band shape extending along the gate wiring 32. The single gate contact opening 36 may have a portion extending in a band shape in the first direction X and a portion extending in a band shape in the second direction Y in plan view.

Referring to FIG. 1, etc., the semiconductor device 1 includes the source pad electrode 37 as an example of a principal surface electrode disposed on the interlayer insulating layer 33. The source pad electrode 37 is a terminal electrode to which a source potential is externally applied. The source pad electrode 37 may be referred to as a “first pad electrode,” a “first principal surface electrode,” a “first terminal electrode,” etc.

The source pad electrode 37 is disposed on a portion of the interlayer insulating layer 33 covering the active region 8. The source pad electrode 37 covers the plurality of gate electrodes 22 with the interlayer insulating layer 33 interposed therebetween, and is electrically separated from the plurality of gate electrodes 22 by the interlayer insulating layer 33. The source pad electrode 37 is in ohmic contact with the plurality of body regions 10, the outer body region 13, the plurality of source regions 15, the contact region 17, etc., via the plurality of contact openings 34, and is in Schottky junction with the Schottky region 12.

As a result, with reference to FIGS. 12A and 13A, a Schottky barrier diode 38 having the source pad electrode 37 as an anode and the Schottky region 12 (the first semiconductor region 6) as a cathode is formed. On the other hand, referring to FIG. 9B, a body diode 39 having the body region 10 as an anode and the first semiconductor region 6 as a cathode is formed.

Referring to FIGS. 1 to 3, in this embodiment, the source pad electrode 37 includes a first pad portion 40, a second pad portion 41, and a third pad portion 42.

The first pad portion 40 has a relatively large plane area, and forms a main body of the source pad electrode 37. In this embodiment, the first pad portion 40 is formed in a polygonal shape (a quadrangular shape in this embodiment) having four sides parallel to the peripheral edges of the chip 2 in plan view, and is shifted further to the fourth side surface 5D side with respect to a central portion of the active region 8.

The second pad portion 41 has a plane area less than the plane area of the first pad portion 40, and is led out in a band shape (quadrangular shape) from one end portion (end portion on the first side surface 5A side) of the first pad portion 40 in the first direction X toward the third side surface 5C.

The third pad portion 42 has a plane area less than the plane area of the first pad portion 40, is led out in a band shape (quadrangular shape) from the other end portion (end portion on the second side surface 5B side) of the first pad portion 40 in the first direction X toward the third side surface 5C, and faces the second pad portion 41 in the first direction X.

The plane area of the third pad portion 42 may be substantially equal to the plane area of the second pad portion 41. As a matter of course, the plane area of the third pad portion 42 may be larger than the plane area of the second pad portion 41, or may be less than the plane area of the second pad portion 41. Either or both of the second pad portion 41 and the third pad portion 42 may be used as a terminal portion for current monitoring.

The source pad electrode 37 does not necessarily have to include both the second pad portion 41 and the third pad portion 42 at the same time. The source pad electrode 37 may include only one of the second pad portion 41 and the third pad portion 42. As a matter of course, the source pad electrode 37 may be constituted of only the first pad portion 40, and does not have to include the second pad portion 41 and the third pad portion 42.

The source pad electrode 37 may have a laminated structure of a barrier layer such as a Ti film and a TiN film, and an electrode layer such as an Al film. The electrode layer may include at least one among an Al film, an Al alloy film, a Cu film, and a Cu alloy film. The Al alloy film may include at least one among an AlSi alloy film, an AlCu alloy film, and an AlSiCu alloy film.

The semiconductor device 1 includes a source finger electrode 43 led out from the source pad electrode 37 onto the outer peripheral region 9. The source finger electrode 43 transmits the source potential applied to the source pad electrode 37 to the outer peripheral region 9. In this embodiment, the source finger electrode 43 is routed from a portion of the source pad electrode 37 (the first pad portion 40) on the fourth side surface 5D side onto a portion of the interlayer insulating layer 33 covering the outer peripheral region 9.

The source finger electrode 43 is led out above the terminal region 28, and is electrically connected to the terminal region 28 through the plurality of outer contact openings 35. Specifically, the source finger electrode 43 is electrically connected to the overlap region 29 of the terminal region 28 through the plurality of outer contact openings 35.

The source finger electrode 43 extends in a band shape along the terminal region 28 (the overlap region 29). The source finger electrode 43 has a portion extending in a band shape in the first direction X and a portion extending in a band shape in the second direction Y in plan view. In this embodiment, the source finger electrode 43 is formed in a polygonal annular shape (in this embodiment, a quadrangular annular shape) having four sides parallel to the peripheral edges of the first principal surface 3, and surrounds the source pad electrode 37. The source finger electrode 43 may have an edge portion connecting the portion extending in the first direction X and the portion extending in the second direction Y in plan view in an arcuate shape (preferably a quadrant arcuate shape) (see FIG. 4).

The semiconductor device 1 includes a gate finger electrode 44 selectively routed on the interlayer insulating layer 33. The gate finger electrode 44 transmits a gate potential to the gate wiring 32. The gate finger electrode 44 is routed on a portion of the interlayer insulating layer 33 covering the gate wiring 32 (that is, on the outer peripheral region 9), and is electrically connected to the gate wiring 32 through the plurality of gate contact openings 36.

The gate finger electrode 44 is disposed in a region between the source pad electrode 37 and the source finger electrode 43 at an interval from the source pad electrode 37 and the source finger electrode 43. The gate finger electrode 44 is disposed on the gate wiring 32 and extends in a band shape along the gate wiring 32. The gate finger electrode 44 has a portion extending in a band shape in the first direction X and a portion extending in a band shape in the second direction Y in plan view.

In this embodiment, the gate finger electrode 44 is formed in a band shape with ends having four sides parallel to the peripheral edges of the first principal surface 3, and surrounds the source pad electrode 37. The gate finger electrode 44 may have an edge portion connecting the portion extending in the first direction X and the portion extending in the second direction Y in plan view in an arcuate shape (preferably a quadrant arcuate shape) (see FIG. 4). The gate finger electrode 44 has a pair of open ends that allow the source finger electrode 43 to pass therethrough on the fourth side surface 5D side.

The semiconductor device 1 includes a gate pad electrode 45 disposed on the interlayer insulating layer 33. The gate pad electrode 45 is a terminal electrode to which a gate potential is externally applied. The gate pad electrode 45 may be referred to as a “second pad electrode,” a “second principal surface electrode,” a “second terminal electrode,” etc. The gate pad electrode 45 is disposed in a region between the source pad electrode 37 and the source finger electrode 43 at an interval from the source pad electrode 37 and the source finger electrode 43.

In this embodiment, the gate pad electrode 45 is disposed in a region on the third side surface 5C side with respect to the first pad portion 40, and is sandwiched between the second pad portion 41 and the third pad portion 42. That is, the gate pad electrode 45 faces the first pad portion 40 in the first direction X, and faces the second pad portion 41 and the third pad portion 42 in the second direction Y.

The gate pad electrode 45 is formed in a polygonal shape (a quadrangular shape in this embodiment) having four sides parallel to the peripheral edges of the chip 2 in plan view. The gate pad electrode 45 has a plane area less than a plane area of the source pad electrode 37 (the first pad portion 40). The gate pad electrode 45 may have a plane area less than the plane area of the second pad portion 41 (the third pad portion 42).

The gate pad electrode 45 is disposed on a portion covering the active region 8 and the outer peripheral region 9, and is connected to the gate finger electrode 44. The gate pad electrode 45 may cover the plurality of gate electrodes 22 with the interlayer insulating layer 33 interposed therebetween, or may cover the gate wiring 32 with the interlayer insulating layer 33 interposed therebetween.

The gate potential applied to the gate pad electrode 45 is applied to the gate wiring 32 through the gate finger electrode 44. The gate potential is transmitted to the plurality of gate electrodes 22 through a wiring path (current path) along the gate wiring 32. As a result, the plurality of gate electrodes 22 are turned on, and on/off of the plurality of channel regions 16 is controlled.

The semiconductor device 1 includes a drain pad electrode 46 covering the second principal surface 4. The drain pad electrode 46 is a terminal electrode to which a drain potential is externally applied. The drain pad electrode 46 may be referred to as a “third pad electrode,” a “third principal surface electrode,” a “third terminal electrode,” etc. The drain pad electrode 46 is electrically connected to the second semiconductor region 7. The drain pad electrode 46 may cover an entire region of the second principal surface 4 such as to be continuous with the peripheral edges (the first to fourth side surfaces 5A to 5D) of the second principal surface 4. The drain pad electrode 46 may partially cover the second principal surface 4 such as to expose a peripheral edge portion of the second principal surface 4.

A breakdown voltage that can be applied between the source pad electrode 37 and the drain pad electrode 46 (between the first principal surface 3 and the second principal surface 4) may be 500 V or more and 3000 V or less. The breakdown voltage may have a value belonging to at least one range among 500 V or more and 1000 V or less, 1000 V or more and 1500 V or less, 1500 V or more and 2000 V or less, 2000 V or more and 2500 V or less, and 2500 V or more and 3000 V or less.

For example, when the semiconductor device 1 is used in an inverter circuit, a free wheeling diode for consuming the current remaining in the inductance component when the MISFET is turned off may be required. By causing a current to flow through the free wheeling diode, energy accumulated in the inductance can be output, and a surge voltage, etc., applied to the MISFET can be reduced. As the free wheeling diode, the above-described body diode 39 can be used, in this embodiment, the Schottky barrier diode 38 can be used as well.

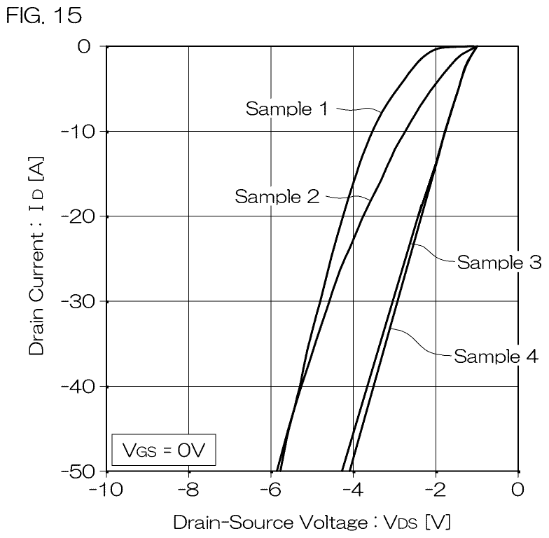

FIG. 15 is a graph showing measurement results of current-voltage characteristics showing an effect of suppressing current-induced degradation. More specifically, V_{DS}-I_{D} characteristics of the SiC-MISFET are illustrated. In FIG. 15, Sample 1 is a MISFET not including the above-described Schottky region 12, and includes only the body diode as the free wheeling diode. Sample 2 is a MISFET including the Schottky region 12 (the Schottky barrier diode 38) and the contact region 17 (the body diode 39) in the layout of FIG. 6.

Each of Sample 3 and Sample 4 includes a Schottky region, but unlike the layout of FIG. 6, is separately provided with a formation region of a Schottky region larger than the Schottky region 12. That is, in Samples 3 and Sample 4, a Schottky barrier diode having an area (region) larger than that of the Schottky barrier diode 38 is formed. When comparing Sample 3 and Sample 4, the Schottky barrier diode of Sample 4 has a larger area.

The profile of each of Samples 1 to 4 in FIG. 15 is a profile under a condition that a negative voltage is applied to the drain with reference to the source of the SiC-MISFET and the gate voltage is 0 V (V_{GS}=0 V).

From the result of FIG. 15, in Sample 1, since only the body diode functions as the free wheeling diode, the rising voltage is higher than that of each of Samples 2 to 4, and bipolar energization by the pn junction is dominant. Therefore, current-induced degradation such as an increase in on-resistance and an increase in drain leak current of the MISFET occurs in some cases. The current-induced degradation is a mode in which, for example, when a forward current continues to flow through a MISFET or a body diode, a defect called a laminating fault is expanded by recombination energy of electron-hole pairs, which affects a current path and increases an on-resistance or a forward voltage of the body diode.

On the other hand, in Samples 2 to 4, since the Schottky barrier diode can be used as the free wheeling diode, the rising voltage of the free wheeling diode is lower than that of Sample 1, and the rectification effect by the free wheeling diode is high. Further, since the energization time of the body diode is reduced, current-induced degradation caused by the body diode can be suppressed.

Further, when comparing Samples 2 to 4, in Samples 3 and 4, the Schottky barrier diode having a relatively large area is formed, and thus unipolar energization based on the Schottky barrier diode is dominant over a range from a low current region to a high current region. As a result, a high rectification effect can be obtained over a range from a low current region to a high current region, but the MISFET structure needs to be sacrificed in order to form a Schottky region having a large area. Therefore, the channel density of the MISFET decreases, and the on-resistance increases. In particular, in an aspect in which a miniaturized structure is required along with the evolution of the element structure, there is a concern about further increase in on-resistance.

On the other hand, in Sample 2, since the area of the Schottky barrier diode 38 is smaller than that in each of Samples 3 and 4, unipolar energization based on the Schottky barrier diode 38 is dominant in the low current region, but the energization is shifted to bipolar energization based on the body diode 39 in the high current region. Although there is a concern about current-induced degradation caused by the body diode 39, it is possible to suppress the current-induced degradation by suppressing the amount of current at the time of the bipolar energization to be less than a threshold at which the current-induced degradation occurs.

Also, as illustrated in FIG. 6, the Schottky region 12 is selectively formed such as to divide each body region 10 into the plurality of unit cells 11 and the pattern of the plurality of stripe-shaped body regions 10 (the unit cells 11) can be maintained, such that the MISFET structure is hardly sacrificed. As a result, a decrease in the channel density of the MISFET can be suppressed, and an increase in the on-resistance can be suppressed. That is, according to the semiconductor device 1 of the present disclosure, it is possible to achieve both suppression of an increase in the on-resistance of the MIS structure and suppression of the current-induced degradation caused by the body diode. In particular, in the semiconductor device 1 having a miniaturized structure in which the pitch P of the plurality of body regions 10 is 3 μm or more and 5 μm or less, the Schottky region 12 can be disposed with high space efficiency.

Also, the plurality of Schottky regions 12 (the Schottky barrier diodes 38) and the plurality of contact regions 17 are alternately arrayed in a staggered manner in the first direction X and the second direction Y. As a result, a current flowing through the Schottky barrier diode 38 can be widely dispersed, such that current concentration can be suppressed.

Although preferred embodiments of the present disclosure have been described above, the present disclosure can be implemented in yet other preferred embodiments.

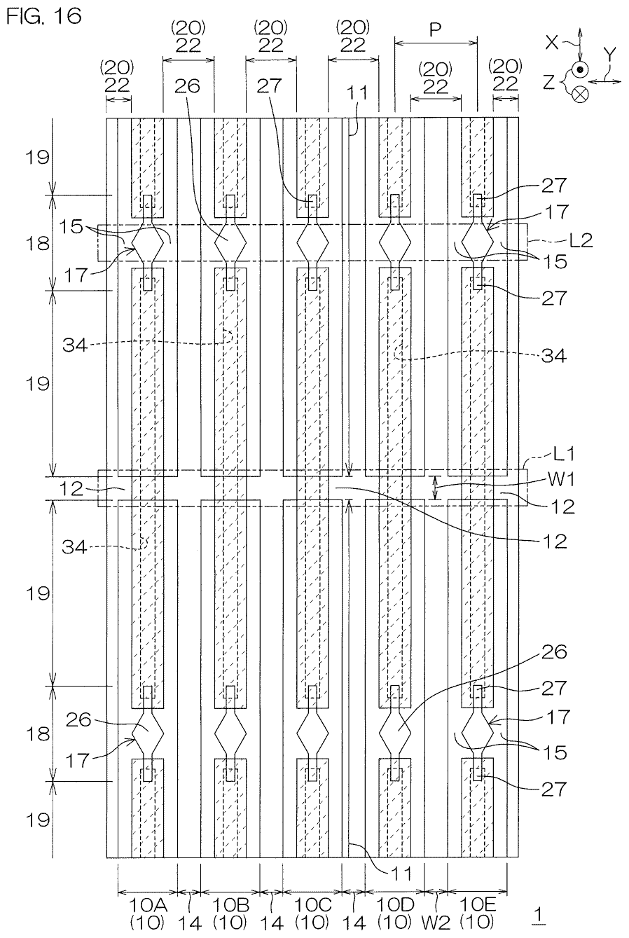

For example, in FIG. 6, in each of the first array line L1 and the second array line L2, the plurality of Schottky regions 12 and the plurality of contact regions 17 are alternately arrayed. On the other hand, the plurality of Schottky regions 12 and the plurality of contact regions 17 may be aggregated into one array line. For example, referring to FIG. 16, only the plurality of Schottky regions 12 may be arrayed in the first array line L1, and only the plurality of contact regions 17 may be arrayed in the second array line L2.

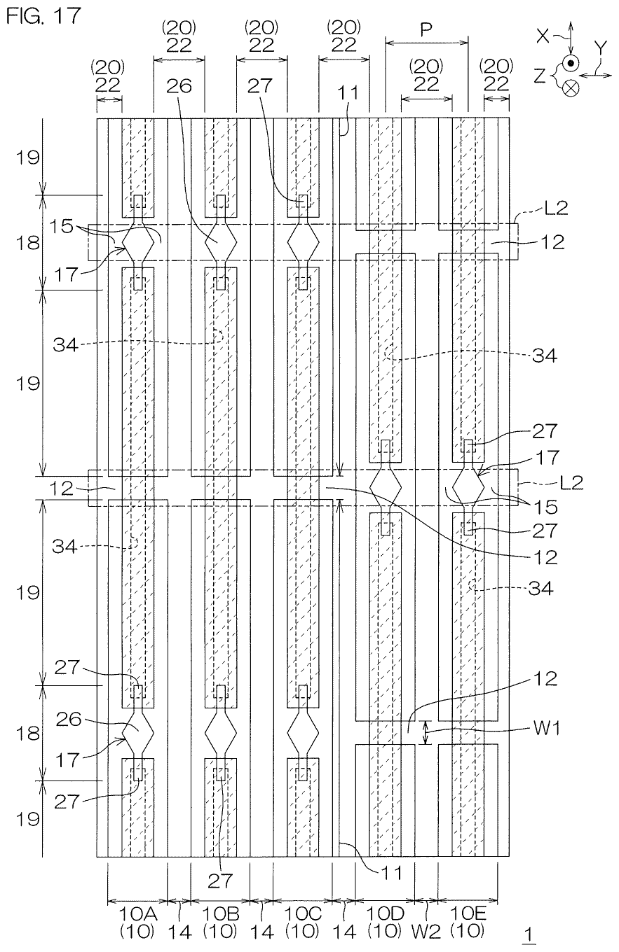

Also, referring to FIG. 17, in each of the first array line L1 and the second array line L2, either one of the plurality of Schottky regions 12 and the plurality of contact regions 17 may be continuously arrayed, and subsequently the other may be continuously arrayed. In FIG. 17, in the first array line L1, three Schottky regions 12 are continuously arrayed, and subsequently, two contact regions 17 are continuously arrayed. Also, in the second array line L2, three contact regions 17 are continuously arrayed, and subsequently, two Schottky regions 12 are continuously arrayed.

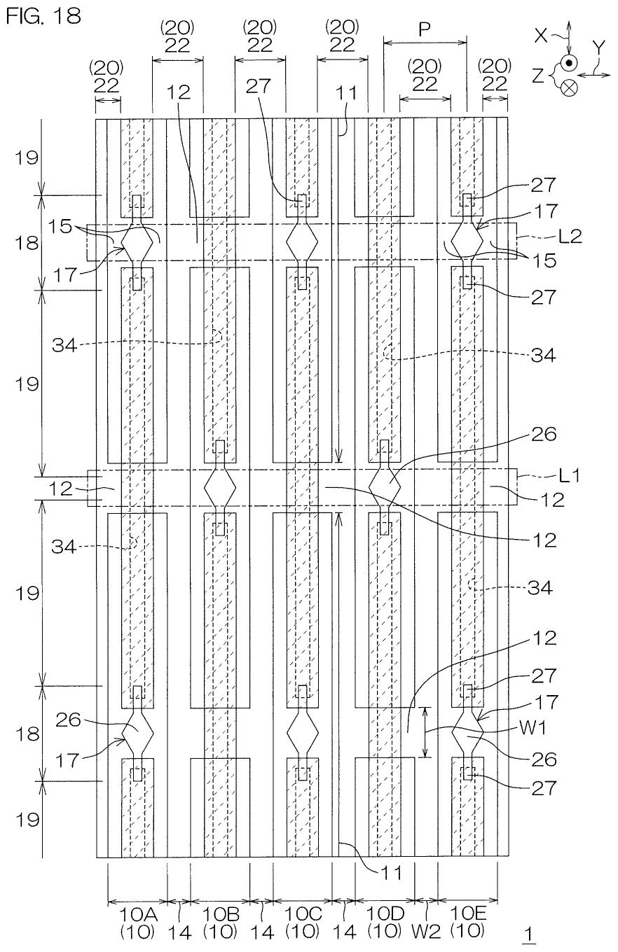

For example, in FIG. 6, the width W1 of the Schottky region 12 in the first direction X is equal to or less than the width W2 between the plurality of adjacent body regions 10 (W1≤W2). On the other hand, referring to FIG. 18, the width W1 may be larger than the width W2 (W1>W2).

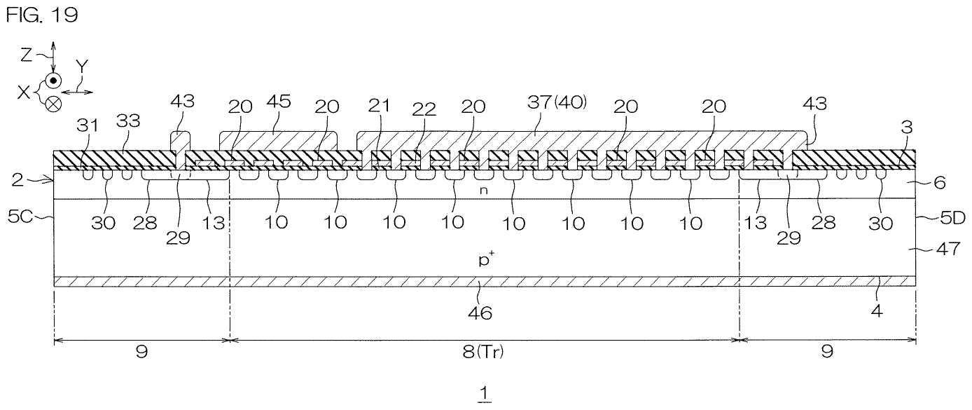

Also, in the preferred embodiment described above, the second semiconductor region 7 of the n-type was illustrated. On the other hand, as illustrated in FIG. 19, a second semiconductor region 47 of the p-type may be adopted instead of the second semiconductor region 7 of the n-type. In this case, an IGBT (insulated gate bipolar transistor) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The second semiconductor region 7 of the p-type may be an impurity region that contains a p-type impurity introduced into a surface layer portion of the second principal surface 4 of the chip 2 by the ion implantation method.

For example, in the above-described preferred embodiments, a configuration in which a relationship between the a-axis direction and the m-axis direction is interchanged may be adopted. A specific configuration in this case can be obtained by interchanging the “a-axis direction (off direction)” and the “m-axis direction (direction orthogonal to off direction)” in the above description and the accompanying drawings.

In the above-described preferred embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and the accompanying drawings.

In the above-described preferred embodiments, the chip 2 (the first semiconductor region 6 and the second semiconductor region 7) containing an SiC monocrystal is adopted. However, the chip 2 (the first semiconductor region 6 and the second semiconductor region 7) may include a monocrystal of a wide bandgap semiconductor other than the SiC monocrystal. The wide bandgap semiconductor is a semiconductor having a bandgap greater than a bandgap of silicon. Examples of the monocrystal of the wide bandgap semiconductor include gallium nitride, diamond, gallium oxide, etc. As a matter of course, the chip 2 (the first semiconductor region 6 and the second semiconductor region 7) may contain a silicon monocrystal.

Hereinafter, examples of features extracted from this description and the attached drawings shall be indicated. Hereinafter, the alphanumeric characters, etc., in parentheses represent the corresponding components, etc., in the preferred embodiments described above, but are not intended to limit the scope of each clause to the preferred embodiments. The “semiconductor device” in the following clauses may be replaced with an “SiC semiconductor device,” a “wide bandgap semiconductor device,” a “semiconductor switching device,” a “MISFET device,” an “IGBT device,” etc., as needed.

### [Clause 1-1]

A semiconductor device (1) including:
a chip (2) having a principal surface (3) on which a semiconductor region (6) of a first conductivity type is formed;
a base impurity region (10) of a second conductivity type formed in a surface layer portion of the semiconductor region (6) and having a band shape that is long in a first direction (X);
a first impurity region (15) formed in a surface layer portion of the base impurity region (10);
a channel region (16) of the second conductivity type formed by a portion of the base impurity region (10) between an outer peripheral edge of the base impurity region (10) and the first impurity region (15);
a gate electrode (22) formed in a band shape that is long in the first direction (X) and facing the channel region (16) via a gate insulating film (21);
a Schottky region (12) formed by a portion of the semiconductor region (6) and dividing the base impurity region (10) into a plurality of unit cells (11) in a second direction (Y) intersecting the first direction (X); and
a principal surface electrode (37) that is in Schottky junction with the Schottky region (12).

According to this configuration, in addition to a body diode (39) formed by a pn junction of the base impurity region (10) and the first impurity region (15), a Schottky barrier diode (38) formed by the Schottky region (12) and the principal surface electrode (37) can be used as a free wheeling diode. As a result, a rising voltage of the free wheeling diode is lower than that of the body diode (39), and a rectification effect by the free wheeling diode can be improved. Further, since an energization time of the body diode (39) is reduced, current-induced degradation caused by the body diode (39) can be suppressed.

Also, the Schottky region (12) is selectively formed such as to divide a body region into the plurality of unit cells (11), and a pattern of the base impurity region (10) (the unit cells (11)) of a band shape can be maintained, such that an element structure is hardly sacrificed. As a result, a decrease in a channel density of the element structure can be suppressed, and an increase in an on-resistance can be suppressed. That is, according to the semiconductor device (1) of the present disclosure, it is possible to achieve both suppression of an increase in the on-resistance of the element structure and suppression of the current-induced degradation caused by the body diode (39). In particular, in the semiconductor device (1) having a miniaturized structure, the Schottky region (12) can be disposed with high space efficiency.

### [Clause 1-2]

The semiconductor device (1) according to Clause 1-1,
wherein a plurality of the base impurity regions (10) are arrayed in a stripe shape at intervals in the second direction (Y), and
wherein a plurality of the Schottky regions (12) dividing each of the plurality of base impurity regions (10) adjacent to each other in the second direction (Y) are disposed at positions shifted from each other in the second direction (Y).

According to this configuration, a current flowing through the Schottky barrier diode (38) can be widely dispersed, such that current concentration can be suppressed.

### [Clause 1-3]

The semiconductor device (1) according to Clause 1-2,
wherein the plurality of Schottky regions (12) include a plurality of first Schottky regions (12A) forming a first array line (L1) in the second direction (Y) and a plurality of second Schottky regions (12B) forming a second array line (L2) in the second direction (Y) at a position shifted from the first array line (L1) in the first direction (X), and
wherein the plurality of first Schottky regions (12A) and the plurality of second Schottky regions (12B) are formed every other of the plurality of base impurity regions (10) arrayed in the second direction (Y).

### [Clause 1-4]

The semiconductor device (1) according to Clause 1-1,
wherein a plurality of the base impurity regions (10) are arrayed in a stripe shape at intervals in the second direction (Y), and
wherein each of the gate electrodes (22) includes a plurality of main body portions (23) arrayed in a stripe shape extending in the first direction (X) as a whole spanning across the channel regions (16) of the plurality of base impurity regions (10) adjacent to each other, and a bridging portion (24) that crosses the base impurity region (10) between the plurality of main body portions (23) adjacent to each other and connects the plurality of adjacent main body portions (23) at a position away from the Schottky region (12) in the first direction (X).

### [Clause 1-5]

The semiconductor device (1) according to Clause 1-4, further including a contact region (17) that is selectively formed in a portion of the base impurity region (10) covered with the bridging portion (24), has a higher impurity concentration than the base impurity region (10), and is connected to the base impurity region (10).

### [Clause 1-6]

The semiconductor device (1) according to Clause 1-5, wherein a plurality of the Schottky regions (12) and a plurality of the contact regions (17) are alternately arrayed in the second direction (Y).

According to this configuration, the current flowing through the Schottky barrier diode (38) can be widely dispersed, such that current concentration can be suppressed.

### [Clause 1-7]

The semiconductor device (1) according to Clause 1-5, wherein a plurality of the Schottky regions (12) and a plurality of the contact regions (17) are alternately arrayed in a staggered manner in the first direction (X) and the second direction (Y).

According to this configuration, the current flowing through the Schottky barrier diode (38) can be widely dispersed, such that current concentration can be suppressed.

### [Clause 1-8]

The semiconductor device (1) according to any one of Clauses 1-2 to 1-7, wherein a first width (W1) of the Schottky region (12) in the first direction (X) is equal to or less than a second width (W2) between the plurality of adjacent base impurity regions (10).

### [Clause 1-9]

The semiconductor device (1) according to Clause 1-8,
wherein the first width (W1) is 0.5 μm or more and 2 μm or less, and
wherein the second width (W2) is 1 μm or more and 4 μm or less.

### [Clause 1-10]

The semiconductor device (1) according to any one of Clauses 1-2 to 1-7, wherein the plurality of base impurity regions (10) are arrayed at a pitch (P) of 3 μm or more and 5 μm or less in the second direction (Y).

### [Clause 1-11]

The semiconductor device (1) according to any one of Clauses 1-1 to 1-10, further including:
an interlayer insulating layer (33) formed on the principal surface (3) of the chip (2); and
a contact opening (34) formed in the interlayer insulating layer (33) such as to span across the plurality of unit cells (11) adjacent to each other with the Schottky region (12) interposed therebetween and exposing the first impurity region (15) and the Schottky region (12),
wherein the principal surface electrode (37) is, inside the contact opening (34), in ohmic contact with the first impurity region (15) and is in Schottky junction with the Schottky region (12).

### [Clause 1-12]

The semiconductor device (1) according to Clause 1-11, wherein a contact width (W3) of the contact opening (34) in the second direction (Y) is 0.3 μm or more and 1 μm or less.

### [Clause 1-13]

The semiconductor device (1) according to Clause 1-12, wherein an aspect ratio (D/W3) of the contact opening (34) obtained by dividing a contact depth (D) of the contact opening (34) by the contact width (W3) is 0.5 or more and 2 or less.

### [Clause 1-14]

The semiconductor device (1) according to any one of Clauses 1-5 to 1-7,
wherein the contact region (17) includes a contact portion (27) protruding outward from the bridging portion (24) in the first direction (X) and exposed,
wherein the semiconductor device (1) further includes:
an interlayer insulating layer (33) formed on the principal surface (3) of the chip (2) such as to cover the gate electrode (22); and
a contact opening (34) formed in the interlayer insulating layer (33) such as to extend in a band shape in the first direction (X) and collectively exposing the first impurity region (15), the Schottky region (12), and the contact portion (27), and
wherein the principal surface electrode (37) is, inside the contact opening (34), in ohmic contact with the first impurity region (15) and the contact portion (27) and is in Schottky junction with the Schottky region (12).

### [Clause 1-15]

The semiconductor device (1) according to any one of Clauses 1-1 to 1-14,
wherein the base impurity region (10) is a body region (10), and the first impurity region (15) is a source region (15), and
wherein a MISFET structure is formed by the body region (10), the source region (15), the gate insulating film (21), and the gate electrode (22).

### [Clause 1-16]

The semiconductor device (1) according to any one of Clauses 1-1 to 1-14, wherein the chip (2) is a semiconductor chip (2) formed of a wide bandgap semiconductor.

1. A semiconductor device comprising:
a chip having a principal surface on which a semiconductor region of a first conductivity type is formed;
a base impurity region of a second conductivity type formed in a surface layer portion of the semiconductor region and having a band shape that is long in a first direction;
a first impurity region formed in a surface layer portion of the base impurity region;
a channel region of the second conductivity type formed by a portion of the base impurity region between an outer peripheral edge of the base impurity region and the first impurity region;
a gate electrode formed in a band shape that is long in the first direction and facing the channel region via a gate insulating film;
a Schottky region formed by a portion of the semiconductor region and dividing the base impurity region into a plurality of unit cells in a second direction intersecting the first direction; and
a principal surface electrode that is in Schottky junction with the Schottky region.

2. The semiconductor device according to claim 1,
wherein a plurality of the base impurity regions are arrayed in a stripe shape at intervals in the second direction, and
wherein a plurality of the Schottky regions dividing each of the plurality of base impurity regions adjacent to each other in the second direction are disposed at positions shifted from each other in the second direction.

3. The semiconductor device according to claim 2,
wherein the plurality of Schottky regions include a plurality of first Schottky regions forming a first array line in the second direction and a plurality of second Schottky regions forming a second array line in the second direction at a position shifted from the first array line in the first direction, and
wherein the plurality of first Schottky regions and the plurality of second Schottky regions are formed every other of the plurality of base impurity regions arrayed in the second direction.

4. The semiconductor device according to claim 1,
wherein a plurality of the base impurity regions are arrayed in a stripe shape at intervals in the second direction, and
wherein each of the gate electrodes includes a plurality of main body portions arrayed in a stripe shape extending in the first direction as a whole spanning across the channel regions of the plurality of base impurity regions adjacent to each other, and a bridging portion that crosses the base impurity region between the plurality of main body portions adjacent to each other and connects the plurality of adjacent main body portions at a position away from the Schottky region in the first direction.

5. The semiconductor device according to claim 4, further comprising a contact region that is selectively formed in a portion of the base impurity region covered with the bridging portion, has a higher impurity concentration than the base impurity region, and is connected to the base impurity region.

6. The semiconductor device according to claim 5, wherein a plurality of the Schottky regions and a plurality of the contact regions are alternately arrayed in the second direction.

7. The semiconductor device according to claim 5, wherein a plurality of the Schottky regions and a plurality of the contact regions are alternately arrayed in a staggered manner in the first direction and the second direction.

8. The semiconductor device according to claim 2, wherein a first width of the Schottky region in the first direction is equal to or less than a second width between the plurality of adjacent base impurity regions.

9. The semiconductor device according to claim 8,
wherein the first width is 0.5 μm or more and 2 μm or less, and
wherein the second width is 1 μm or more and 4 μm or less.

10. The semiconductor device according to claim 2, wherein the plurality of base impurity regions are arrayed at a pitch of 3 μm or more and 5 μm or less in the second direction.

11. The semiconductor device according to claim 1, further comprising:
an interlayer insulating layer formed on the principal surface of the chip; and
a contact opening formed in the interlayer insulating layer such as to span across the plurality of unit cells adjacent to each other with the Schottky region interposed therebetween and exposing the first impurity region and the Schottky region,
wherein the principal surface electrode is, inside the contact opening, in ohmic contact with the first impurity region and is in Schottky junction with the Schottky region.

12. The semiconductor device according to claim 11, wherein a contact width of the contact opening in the second direction is 0.3 μm or more and 1 μm or less.

13. The semiconductor device according to claim 12, wherein an aspect ratio of the contact opening obtained by dividing a contact depth of the contact opening by the contact width is 0.5 or more and 2 or less.

14. The semiconductor device according to claim 5,
wherein the contact region includes a contact portion protruding outward from the bridging portion in the first direction and exposed,
wherein the semiconductor device further comprises:
an interlayer insulating layer formed on the principal surface of the chip such as to cover the gate electrode; and
a contact opening formed in the interlayer insulating layer such as to extend in a band shape in the first direction and collectively exposing the first impurity region, the Schottky region, and the contact portion, and
wherein the principal surface electrode is, inside the contact opening, in ohmic contact with the first impurity region and the contact portion and is in Schottky junction with the Schottky region.

15. The semiconductor device according to claim 1,
wherein the base impurity region is a body region, and the first impurity region is a source region, and
wherein a MISFET structure is formed by the body region, the source region, the gate insulating film, and the gate electrode.

16. The semiconductor device according to claim 1, wherein the chip is a semiconductor chip formed of a wide bandgap semiconductor.
